(19) United States
(12) Patent Application Publication
(10) Pub. No.: US 2025/0056959 A1
(43) Pub. Date: Feb. 13, 2025

(54) LIGHT-EMITTING ELEMENT, DISPLAY DEVICE, METHOD FOR PRODUCING LIGHT-EMITTING ELEMENT, AND METHOD FOR PRODUCING DISPLAY DEVICE

(71) Applicant: Sharp Display Technology Corporation, Kameyama City, Mie (JP)

(72) Inventor: YUSUKE SAKAKIBARA, Sakai City, Osaka (JP)

(21) Appl. No.: 18/717,409

(22) PCT Filed: Feb. 10, 2022
(86) PCT No.: PCT/JP2022/005468

§ 371 Date: Jun. 6, 2024

(51) Int. Cl. H10K 50/115; B82Y 20/00; B82Y 30/00; B82Y 40/00; H10K 71/20

(52) U.S. Cl. CPC H10K 50/115; H10K 71/221; B82Y 20/00; B82Y 30/00; B82Y 40/00

(57) ABSTRACT

A blue light-emitting element includes a first electrode and a second electrode, and a function layer placed between the first electrode and the second electrode and including at least a blue light-emitting layer containing quantum dots. The blue light-emitting layer contains at least some amount of first ligands, which are at least one type of ligand selected from a ligand being a halogen atom and a ligand being a sulfur atom, and includes a first region, which is a partial region of the blue light-emitting layer including at least part of an end portion of the blue light-emitting layer, and a second region other than the first region. The number of the first ligands contained per unit volume in the first region is greater than the number of the first ligands contained per unit volume in the second region.

### TECHNICAL FIELD

The disclosure relates to a light-emitting element, a display device, a method of manufacturing a light-emitting element, and a method of manufacturing a display device.

### BACKGROUND ART

In recent years, quantum dot light emitting diodes (QLEDs), which are light-emitting elements, and display devices provided with QLEDs have been attracting a lot of attention.

However, light-emitting characteristics and reliability of light-emitting layers containing quantum dots included in QLEDs are not satisfactory, and research is actively being conducted to improve the light-emitting characteristics and reliability.

For example, PTL 1 describes a quantum dot composition in which a fluoride containing ligand or a fluoride anion is bound to a surface of a quantum dot, a light-emitting layer containing quantum dots and fluoride containing ligands or fluoride anions bound to surfaces of the quantum dots, and an electroluminescent device including such a light-emitting layer.

### CITATION LIST

### Patent Literature

PTL 1: JP 2020-180278 A

### SUMMARY

### Technical Problem

In a case of a light-emitting layer containing quantum dots, there is a problem in that the quantum dots in a peripheral portion of the light-emitting layer, which is a partial region of the light-emitting layer including an end portion of the light-emitting layer, deteriorate over time due to impurities and foreign matter entering from the end portion of the light-emitting layer, resulting in non-emissive. Note that the end portion of the light-emitting layer means part of the light-emitting layer formed by multiple quantum dots forming a side surface of the light-emitting layer among the multiple quantum dots contained in the light-emitting layer.

In a case of forming a light-emitting layer containing quantum dots using the quantum dot composition described in PTL 1 and in a case of the light-emitting layer described in PTL 1, the number of fluoride containing ligands or fluoride anions contained per unit volume in the light-emitting layer does not differ between the peripheral portion of the light-emitting layer, which is a partial region of the light-emitting layer, and a central portion of the light-emitting layer, which is a portion other than the peripheral portion of the light-emitting layer. Note that the unit volume of the light-emitting layer means part of the light-emitting layer having a size of 1 μm (thickness)×1 μm (width)×1 μm (length).

Therefore, when the number of the fluoride containing ligands or the fluoride anions contained per unit volume in the entire light-emitting layer is increased to a level preferable for suppressing impurities or foreign matter entering from the end portion of the light-emitting layer, deterioration of quantum dots in the peripheral portion of the light-emitting layer can be suppressed, thereby improving the reliability. However, the fluoride containing ligands or the fluoride anions are present in excess also in the central portion of the light-emitting layer, causing problems such as generation of leakage current due to aggregation of quantum dots (QDs) and unevenness of a surface of the light-emitting layer, which results in a decrease in the light-emitting characteristics of the light-emitting layer.

On the other hand, when the number of the fluoride containing ligands or the fluoride anions contained per unit volume in the entire light-emitting layer is reduced to a level that does not increase the unevenness of the surface of the light-emitting layer, the light-emitting characteristics of the light-emitting layer can be improved, but there is a problem in that the deterioration of the quantum dots cannot be suppressed in the peripheral portion of the light-emitting layer, resulting in reduced reliability.

An aspect of the disclosure has been made in view of the above-mentioned problems, and an object of the aspect of the disclosure is to provide a light-emitting element, a method of manufacturing a light-emitting element, a display device, and a method of manufacturing a display device that can both protect quantum dots in a peripheral portion of a light-emitting layer, that is, ensure reliability, and ensure light-emitting characteristics of the light-emitting layer.

### Solution to Problem

In order to solve the above problems, a light-emitting element according to the disclosure includes a first electrode and a second electrode, and a function layer placed between the first electrode and the second electrode and including at least a light-emitting layer containing quantum dots, in which the light-emitting layer contains at least some amounts of first ligands, the first ligands being at least one type of ligand selected from a ligand being a halogen atom and a ligand being a sulfur atom, and includes a first region being a partial region of the light-emitting layer including at least part of an end portion of the light-emitting layer and a second region other than the first region, and the number of the first ligands contained per unit volume in the first region is greater than the number of the first ligands contained per unit volume in the second region.

In order to solve the above problems, a method of manufacturing a light-emitting element according to the disclosure includes forming a first electrode, forming a first light-emitting layer on the first electrode, and forming a second electrode on the first light-emitting layer, in which the forming a first light-emitting layer includes forming a first quantum dot layer on the first electrode, forming a photosensitive resin layer on an entire surface, by exposing and developing the photosensitive resin layer, removing the photosensitive resin layer on a first region being a partial region of the first quantum dot layer including at least part of an end portion of the first quantum dot layer and leaving the photosensitive resin layer on a second region of the first quantum dot layer other than the first region, forming a layer obtained by a solution containing first ligands on the first region of the first quantum dot layer, the first ligands being at least one type of ligand selected from a ligand being a halogen atom and a ligand being a sulfur atom, and after the forming a layer obtained by a solution containing first ligands on the first region of the first quantum dot layer, removing the photosensitive resin layer.

### Advantageous Effects of Disclosure

According to the aspect of the disclosure, it is possible to provide a light-emitting element, a method of manufacturing a light-emitting element, a display device, and a method of manufacturing a display device that can both protect quantum dots in a peripheral portion of a light-emitting layer, that is, ensure reliability, and ensure light-emitting characteristics of the light-emitting layer.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a display region of the display device according to the first embodiment.

FIG. 3 is a cross-sectional view illustrating a schematic configuration of a light-emitting element included in the display device according to the first embodiment.

FIG. 4 is a plan view of light-emitting layers included in light-emitting elements included in subpixels of the display device according to the first embodiment, respectively.

FIG. 5(a) is a diagram illustrating sizes of a peripheral portion and a central portion of the light-emitting layer included in the light-emitting element included in each subpixel of the display device according to the first embodiment, and FIG. 5(b) is a diagram showing a relationship between a peripheral width of the light-emitting layer and a ratio of an area of the peripheral portion to an area of one subpixel and a ratio of an area of the central portion to the area of one subpixel.

FIGS. 6(a) to 6(o) are diagrams illustrating an example of steps of a process of forming quantum dot layers, which is part of a process of forming the light-emitting layers included in the light-emitting elements included in the respective subpixels of the display device according to the first embodiment, by a lift-off method.

FIGS. 7(a), 7(b), 7(c), 7(d), and 7(e) are diagrams illustrating remaining steps of the process of forming the light-emitting layer performed after the process of forming quantum dot layers illustrated in FIG. 6.

FIG. 8 is a cross-sectional view illustrating a schematic configuration of a modification of the light-emitting element included in the display device according to the first embodiment illustrated in FIG. 3.

FIGS. 9(a) to 9(j) are diagrams illustrating some steps of still another process of forming a red light-emitting layer, a green light-emitting layer, and a blue light-emitting layer included in a display device 1 according to the first embodiment.

FIGS. 10(a) to 10(j) are diagrams illustrating subsequent steps of the steps illustrated in (a) to (j) of FIG. 9.

FIGS. 11(a) to 11(j) are diagrams illustrating subsequent steps of the steps illustrated in (a) to (j) of FIG. 10.

FIG. 12 is a plan view of light-emitting layers included in light-emitting elements included in subpixels of a display device according to a second embodiment, respectively.

FIGS. 13(a) to 13(e) are diagrams illustrating some steps of a process of forming the light-emitting layers included in the light-emitting elements included in the respective subpixels of the display device according to the second embodiment.

FIGS. 14(a) to 14(e) are diagrams illustrating some steps of still another process of forming the light-emitting layers included in the light-emitting elements included in the respective subpixels of the display device according to the second embodiment.

FIG. 15 is a plan view of light-emitting layers included in light-emitting elements included in subpixels of a display device according to a third embodiment, respectively.

FIG. 16 is a plan view of light-emitting layers included in light-emitting elements included in subpixels of a display device according to a fourth embodiment, respectively.

### DESCRIPTION OF EMBODIMENTS

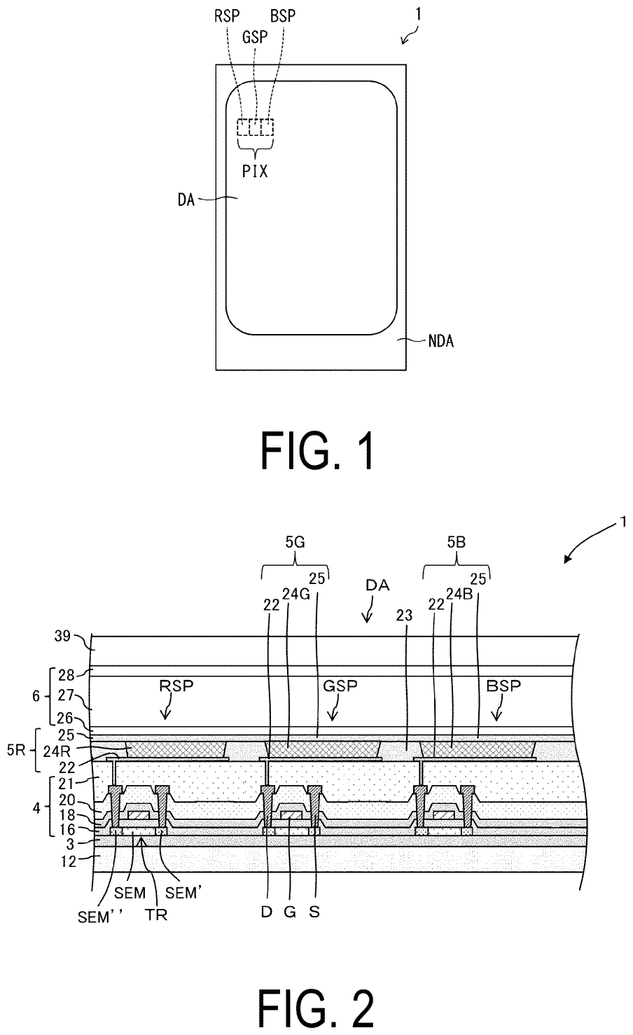

The following is a description of embodiments of the disclosure, with reference to FIG. 1 to FIG. 16. Hereinafter, for convenience of description, configurations having the same functions as those described in a specific embodiment are denoted by the same reference signs, and descriptions thereof will be omitted.

### First Embodiment

FIG. 1 is a schematic plan view illustrating a configuration of a display device 1 according to a first embodiment.

As illustrated in FIG. 1, the display device 1 includes a frame region NDA and a display region DA. A plurality of pixels PIX are provided in the display region DA of the display device 1, and each pixel PIX includes a red subpixel RSP, a green subpixel GSP, and a blue subpixel BSP. In the present embodiment, a case will be described as an example in which one pixel PIX includes the red subpixel RSP, the green subpixel GSP, and the blue subpixel BSP, but the disclosure is not limited thereto. For example, one pixel PIX may further include a subpixel of another color in addition to the red subpixel RSP, the green subpixel GSP, and the blue subpixel BSP.

FIG. 2 is a cross-sectional view illustrating a schematic configuration of the display region DA of the display device 1 according to the first embodiment.

As illustrated in FIG. 2, in the display region DA of the display device 1, a barrier layer 3, a thin film transistor layer 4 including transistors TR, a red light-emitting element 5R, a green light-emitting element 5G, a blue light-emitting element 5B, and a bank 23, a sealing layer 6, and a function film 39 are provided on a substrate 12 in this order from the substrate 12 side.

The blue subpixel BSP included in the display region DA of the display device 1 includes the blue light-emitting element 5B (first light-emitting element), the green subpixel GSP included in the display region DA of the display device 1 includes the green light-emitting element 5G (second light-emitting element), and the red subpixel RSP included in the display region DA of the display device 1 includes the red light-emitting element 5R (third light-emitting element).

The substrate 12 may be, for example, a resin substrate made of a resin material such as polyimide, or may be a glass substrate. In the present embodiment, the display device 1 is a flexible display device, and thus a case will be described as an example in which the resin substrate made of the resin material such as polyimide is used as the substrate 12. However, the disclosure is not limited thereto. In a case where the display device 1 is a non-flexible display device, the glass substrate may be used as the substrate 12.

The barrier layer 3 is a layer that inhibits foreign matter, such as water and oxygen, from entering the transistor TR, the red light-emitting element 5R, the green light-emitting element 5G, and the blue light-emitting element 5B, and can be formed of, for example, a silicon oxide film, a silicon nitride film, or a silicon oxynitride film, or a layered film thereof formed by chemical vapor deposition (CVD).

The transistor TR portion of the thin film transistor layer 4 including the transistor TR includes a semiconductor film SEM, doped semiconductor films SEM′ and SEM″, an inorganic insulating film 16, a gate electrode G, an inorganic insulating film 18, an inorganic insulating film 20, a source electrode S, a drain electrode D, and a flattening film 21. A portion other than the transistor TR portion of the thin film transistor layer 4 including the transistor TR includes the inorganic insulating film 16, the inorganic insulating film 18, the inorganic insulating film 20, and the flattening film 21.

The semiconductor films SEM, SEM′ and SEM″ may be formed of low-temperature polysilicon (LTPS) or an oxide semiconductor (for example, an In—Ga—Zn—O based semiconductor), for example. In the example of the present embodiment described herein, the transistor TR has a top gate structure. However, the disclosure is not limited thereto, and the transistor TR may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, and copper.

The inorganic insulating film 16, the inorganic insulating film 18, and the inorganic insulating film 20 can be formed of, for example, a silicon oxide film, a silicon nitride film, or a silicon oxynitride film, or a layered film thereof, formed by CVD.

The flattening film 21 can be formed of coatable organic materials such as polyimide and acrylic.

The red light-emitting element 5R included in the red subpixel RSP includes an anode, which is a first electrode 22 that is an upper layer overlying the flattening film 21, a function layer 24R including a red light-emitting layer, and a cathode, which is a second electrode 25. The green light-emitting element 5G included in the green subpixel GSP includes an anode, which is the first electrode 22 that is an upper layer overlying the flattening film 21, a function layer 24G including the green light-emitting layer, and a cathode, which is the second electrode 25. The blue light-emitting element 5B included in the blue subpixel BSP includes an anode, which is the first electrode 22 that is an upper layer overlying the flattening film 21, a function layer 24B including the blue light-emitting layer, and a cathode, which is the second electrode 25. Note that an insulating bank 23 covering the edge of the anode serving as the first electrode 22 can be formed, for example, by applying an organic material, such as a polyimide or acrylic, and then patterning the organic material by photolithography.

The function layer 24R including the red light-emitting layer may be formed by layering, for example, a hole injection layer, a hole transport layer, the red light-emitting layer, an electron transport layer, and an electron injection layer in this order from the anode side, the anode being the first electrode 22. Of the hole injection layer, the hole transport layer, the electron transport layer, and the electron injection layer in the function layer 24R including the red light-emitting layer, one or more layers may be omitted as appropriate. In the present embodiment, a case is described as an example in which the function layer 24R including the red light-emitting layer is formed by layering the hole transport layer, the red light-emitting layer, and the electron transport layer in this order from the anode side, the anode being the first electrode 22. However, the configuration is not limited thereto.

The function layer 24G including the green light-emitting layer may be formed by layering, for example, the hole injection layer, the hole transport layer, the green light-emitting layer, the electron transport layer, and the electron injection layer in this order from the anode side, the anode being the first electrode 22. Of the hole injection layer, the hole transport layer, the electron transport layer, and the electron injection layer in the function layer 24G including the green light-emitting layer, one or more layers may be omitted as appropriate. In the present embodiment, a case is described as an example in which the function layer 24G including the green light-emitting layer is formed by layering the hole transport layer, the green light-emitting layer, and the electron transport layer in this order from the anode side, the anode being the first electrode 22. However, the configuration is not limited thereto.

The function layer 24B including the blue light-emitting layer may be formed by layering, for example, the hole injection layer, the hole transport layer, the blue light-emitting layer, the electron transport layer, and the electron injection layer in this order from the anode side, the anode being the first electrode 22. Of the hole injection layer, the hole transport layer, the electron transport layer, and the electron injection layer in the function layer 24B including the blue light-emitting layer, one or more layers may be omitted as appropriate. In the present embodiment, a case is described as an example in which the function layer 24B including the blue light-emitting layer is formed by layering the hole transport layer, the blue light-emitting layer, and the electron transport layer in this order from the anode side, the anode being the first electrode 22. However, the configuration is not limited thereto.

In the present embodiment, a case is described as an example in which the function layer 24R including the red light-emitting layer, the function layer 24G including the green light-emitting layer, and the function layer 24B including the blue light-emitting layer each include the hole transport layer formed using the same material in the same process, and the electron transport layer formed using the same material in the same process. However, the configuration is not limited thereto. For example, the function layer 24R including the red light-emitting layer, the function layer 24G including the green light-emitting layer, and the function layer 24B including the blue light-emitting layer each may further include at least one of the hole injection layer formed using the same material in the same process, and the electron injection layer formed using the same material in the same process. In addition, for example, the hole transport layers included respectively in the function layers 24R, 24G, and 24B may be formed of materials different from each other. For example, the hole transport layers included respectively in two function layers of the function layers 24R, 24G, and 24B may be formed of the same material in the same process, and only the hole transport layer included in the remaining one function layer may be formed of a different material in another process. For example, the electron transport layers included respectively in the function layers 24R, 24G, and 24B may be formed of materials different from each other. For example, the electron transport layers included respectively in two function layers of the function layers 24R, 24G, and 24B may be formed of the same material in the same process, and only the electron transport layer included in the remaining one function layer may be formed of a different material in another process. For example, the hole injection layers included respectively in the function layers 24R, 24G, and 24B may be formed of materials different from each other. For example, the hole injection layers each included in a respective one of two function layers of the function layers 24R, 24G, and 24B may be formed of the same material in the same process, and only the hole injection layer included in the remaining one function layer may be formed of a different material in another process. For example, the electron injection layers included respectively in the function layers 24R, 24G, and 24B may be formed of materials different from each other. For example, the electron injection layers included respectively in two function layers of the function layers 24R, 24G, and 24B may be formed of the same material in the same process, and only the electron injection layer included in the remaining one function layer may be formed of a different material in another process.

In the present embodiment, a case will be described as an example in which the red light-emitting element 5R, the green light-emitting element 5G, and the blue light-emitting element 5B are all quantum dot light-emitting diodes (QLEDs), but it is not necessary to be limited to this example, and at least one of the red light-emitting element 5R, the green light-emitting element 5G, and the blue light-emitting element 5B may be a QLED. For example, when one of the red light-emitting element 5R, the green light-emitting element 5G, and the blue light-emitting element 5B is a QLED, the remaining two may be organic light emitting diodes (OLEDs). For example, when two of the red light-emitting element 5R, the green light-emitting element 5G, and the blue light-emitting element 5B are QLEDs, the remaining one may be an OLED.

As in the present embodiment, when all of the red light-emitting element 5R, the green light-emitting element 5G, and the blue light-emitting element 5B are QLEDs, the light-emitting layers included in the respective color light-emitting elements contain quantum dots (QDs). The quantum dots (QDs) may have, for example, a core structure, a core/shell structure, a core/shell/shell structure, or a core/shell with continuously varying ratio structure. Note that the shell may completely cover the core, or may partially cover the core. The core may be composed of, for example, Si, C, or the like in a case of a unitary system, composed of, for example, CdSe, CdS, CdTe, InP, GaP, InN, ZnSe, ZnS, ZnTe, or the like in a case of a binary system, composed of, for example, CdSeTe, GaInP, ZnSeTe, or the like in a case of a ternary system, and composed of, for example, AIGS or the like in a case of a quaternary system. The shell can be composed of, for example, CdS, CdTe, CdSe, ZnS, ZnSe, ZnTe, or the like in a case of a binary system, and composed of, for example, CdSSe, CdTeSe, CdSTe, ZnSSe, ZnSTe, ZnTeSe, AIP, or the like in a case of a ternary system.

Note that the quantum dot (QD) is a dot having a maximum width of 100 nm or less. A shape of the quantum dot (QD) is not limited to a specific shape as long as it is within a range satisfying the maximum width, and is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof.

In the present embodiment, a case will be explained as an example in which the light-emitting layers, containing quantum dots (QDs), of the red light-emitting element 5R, the green light-emitting element 5G, and the blue light-emitting element 5B all contain at least some amounts of first ligands, which are at least one type of ligand selected from a ligand being a halogen atom and a ligand being a sulfur atom, but it is not necessary to be limited to this case. For example, as in a fourth embodiment described later, only the light-emitting layer, containing the quantum dots (QDs), of the blue light-emitting element 5B among the red light-emitting element 5R, the green light-emitting element 5G, and the blue light-emitting element 5B, may contain at least some amounts of first ligands, which are at least one type of ligand selected from a ligand being a halogen atom and a ligand being a sulfur atom.

The ligand is a compound that has a function to coordinate. When both the ligand and the quantum dot (QD) are contained, the ligand can be considered to be coordinating with the quantum dot (QD).

The ligand being a halogen atom means a ligand being a halogen atom such as F, Cl, Br, or I, and is attracted to the surface of the positively charged quantum dot (QD) in an anionic state such as F⁻, Cl⁻, Br⁻, or I⁻. It is preferable that a ligand, which is a halogen atom, be coordinated to the quantum dot (QD) because stability and electron injection properties are improved, and among the halogen atoms, a fluorine atom is more preferable as a ligand that has a strong coordination force to the quantum dot (QD). Therefore, the first ligand is preferably a halogen atom. In the present embodiment, considering the strong coordination force to the quantum dot (QD), a case in which a fluorine atom is used as the first ligand will be described as an example. However, the first ligand is not limited to using a fluorine atom.

The ligand being a sulfur atom means a ligand being a sulfur(S) atom, and is attracted to the surface of the positively charged quantum dot (QD) in a state of an anion of S²⁻, for example. The ligand being a sulfur atom also has a strong coordination force to the quantum dot (QD) and can improve stability.

The light-emitting layer containing quantum dots (QDs) may contain at least some amounts of second ligands, which are ligands other than the first ligands. Examples of the second ligand include, but are not limited to, organic ligands including organic molecules having a certain length in order to prevent quantum dots (QDs) from aggregating with each other. Examples of the organic ligand that can be used include, but are not limited to, oleylamine, oleic acid, dodecanethiol, trioctylphosphine, trioctylphosphine oxide, tributylphosphine oxide, and oleyl alcohol.

The first ligand or the second ligand is provided on a surface of a core when the quantum dot (QD) has a core structure, provided on a surface of a shell when the quantum dot (QD) has a shell structure and the shell completely covers the core, and provided on surfaces of the core and the shell when the quantum dot (QD) has a shell structure and the shell partially covers the core.

A control circuit including the transistors TR each of which controls a respective one of the red light-emitting element 5R, the green light-emitting element 5G, and the blue light-emitting element 5B is provided in the thin film transistor layer 4 including the transistors TR corresponding to the red subpixel RSP, the green subpixel GSP, and the blue subpixel BSP. Note that the control circuit including the transistors TR provided corresponding to the red subpixel RSP, the green subpixel GSP, and the blue subpixel BSP and the light-emitting elements are collectively referred to as a subpixel circuit.

The red light-emitting element 5R, the green light-emitting element 5G, and the blue light-emitting element 5B illustrated in FIG. 2 may be a top-emitting type or a bottom-emitting type. The red light-emitting element 5R, the green light-emitting element 5G, and the blue light-emitting element 5B each have a regular layered structure in which the anode serving as the first electrode 22, the function layer 24R, 24G, or 24B, and the cathode serving as the second electrode 25 are formed in this order from the substrate 12 side, and thus the cathode serving as the second electrode 25 is disposed as an upper layer above the anode serving as the first electrode 22. Therefore, to realize a top-emitting type light-emitting element, the anode serving as the first electrode 22 may be formed of an electrode material that reflects visible light, and the cathode serving as the second electrode 25 may be formed of an electrode material that allows the transmission of visible light. Furthermore, to realize a bottom-emitting type light-emitting element, the anode serving as the first electrode 22 may be formed of an electrode material that allows the transmission of visible light, and the cathode serving as the second electrode 25 may be formed of an electrode material that reflects visible light.

The electrode material that reflects visible light is not particularly limited as long as the material can reflect visible light and has electrical conductivity. Examples include metal materials such as Al, Mg, Li, and Ag, alloys of the metal materials, a layered body of the metal materials and transparent metal oxides (for example, indium tin oxide, indium zinc oxide, indium gallium zinc oxide, and the like), or a layered body of the alloys and the transparent metal oxides.

On the other hand, the electrode material that transmits visible light is not particularly limited as long as the material can transmit visible light and has electrical conductivity. Examples include a thin film formed of a transparent metal oxide (for example, indium tin oxide, indium zinc oxide, indium gallium zinc oxide, and the like) or a metal material such as Al and Ag, or a nano wire formed of a metal material such as Al and Ag.

In the present embodiment, a case is described as an example in which the red light-emitting element 5R, the green light-emitting element 5G, and the blue light-emitting element 5B are top-emitting types, each of the anodes serving as the first electrode 22 is formed of a layered film of ITO/Ag/ITO, which is an electrode material that reflects visible light, and each of the cathodes serving as the second electrode 25 is formed of a thin film formed from Ag, which is an electrode material that transmits visible light. However, the disclosure is not limited thereto.

A typical electrode forming method may be used as a film formation method of the anode serving as the first electrode 22 and the cathode serving as the second electrode 25, and examples thereof include physical vapor deposition (PVD) methods such as vacuum vapor deposition, sputtering, electron beam (EB) vapor deposition, and ion plating, or a chemical vapor deposition (CVD) method. Further, the method of patterning the anode serving as the first electrode 22 and the cathode serving as the second electrode 25 is not particularly limited as long as the method can be used to precisely form a desired pattern, and specific examples include a photolithography method and an ink-jet method.

The sealing layer 6 is a transparent film and, for example, may be formed of an inorganic sealing film 26 for covering the cathode serving as the second electrode 25, an organic film 27 that is an upper layer overlying the inorganic sealing film 26, and an inorganic sealing film 28 that is an upper layer overlying the organic film 27. The sealing layer 6 inhibits foreign matters such as water and oxygen from penetrating into the red light-emitting element 5R, the green light-emitting element 5G, and the blue light-emitting element 5B.

The inorganic sealing film 26 and the inorganic sealing film 28 are both inorganic films and may be formed of, for example, a silicon oxide film, a silicon nitride film, a silicon oxynitride film, or a layered film thereof, formed by CVD. The organic film 27 is a transparent organic film having a flattening effect, and may be formed of a coatable organic material such as acrylic, for example. The organic film 27 may be formed by an ink-jet method, for example. The case has been described as an example of the present embodiment in which the sealing layer 6 is formed of two layers of an inorganic film and one layer of an organic film provided between the two layers of the inorganic film. However, the layering order of the two layers of the inorganic film and the one layer of the organic film is not limited thereto. Further, the sealing layer 6 may be formed of only an inorganic film, may be formed of only an organic film, may be formed of one layer of an inorganic film and two layers of an organic film, or may be formed of two or more layers of an inorganic film and two or more layers of an organic film.

The function film 39 is a film with at least one of an optical compensation function, a touch sensor function, and a protection function, for example.

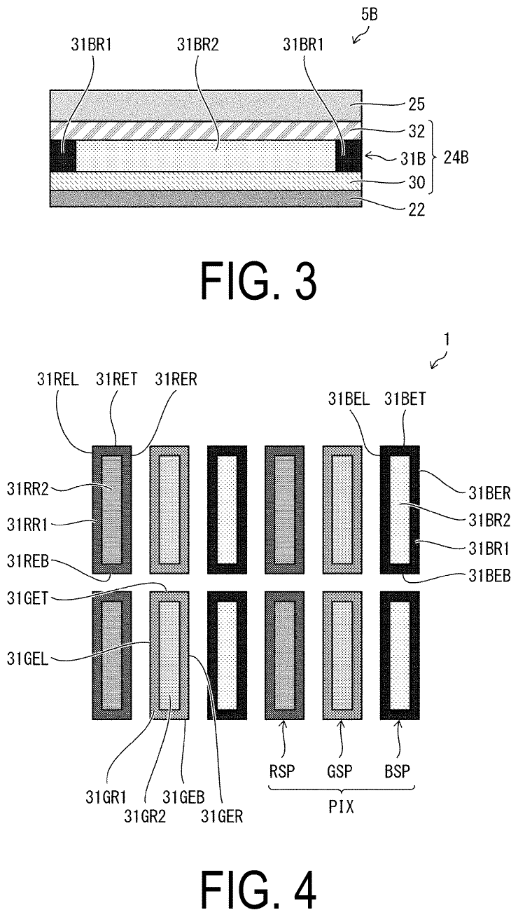

FIG. 3 is a cross-sectional view illustrating a schematic configuration of the blue light-emitting element 5B included in the display device 1 of the first embodiment.

FIG. 4 is a plan view of a red light-emitting layer 31R included in the red light-emitting element 5R included in the red subpixel RSP, a green light-emitting layer 31G included in the green light-emitting element 5G included in the green subpixel GSP, and a blue light-emitting layer 31B included in the blue light-emitting element 5B included in the blue subpixel BSP in the display device 1 according to the first embodiment.

As illustrated in FIG. 3, the blue light-emitting element 5B includes the first electrode 22 and the second electrode 25, and the function layer 24B placed between the first electrode 22 and the second electrode 25 and including at least the blue light-emitting layer 31B containing quantum dots (QDs). The function layer 24B is configured by layering a hole transport layer 30, the blue light-emitting layer 31B, and an electron transport layer 32 in order from the first electrode 22 side.

The blue light-emitting layer 31B included in the blue light-emitting element 5B only needs to contain at least some amounts of first ligands, which are at least one type of ligand selected from a ligand being a halogen atom and a ligand being a sulfur atom, and include a first region 31BR1, which is a partial region of the light-emitting layer 31B including at least part of an end portion of the blue light-emitting layer 31B, and a second region 31BR2 other than the first region 31BR1. That is, the second region 31BR2 of the blue light-emitting layer 31B may or may not be surrounded by the first region 31BR1 of the blue light-emitting layer 31B.

In the present embodiment, as illustrated in FIGS. 3 and 4, a case will be explained as an example in which the blue light-emitting layer 31B included in the blue light-emitting element 5B contains at least some amounts of first ligands, which are at least one type of ligand selected from a ligand being a halogen atom and a ligand being a sulfur atom, and includes the first region 31BR1, which is a partial region of the blue light-emitting layer 31B, including all of an upper end portion 31BET of the blue light-emitting layer 31B, a right end portion 31BER of the blue light-emitting layer 31B, a left end portion 31BEL of the blue light-emitting layer 31B, and a lower end portion 31BEB of the blue light-emitting layer 31B, which are end portions of the blue light-emitting layer 31B, and the second region 31BR2 other than the first region 31BR1, that is, the second region 31BR2 of the blue light-emitting layer 31B is surrounded by the first region 31BR1 of the blue light-emitting layer 31B. But the configuration is not limited thereto.

Note that the end portion of the light-emitting layer (e.g., the end portion of the blue light-emitting layer 31B) means part of the light-emitting layer formed by multiple quantum dots (QDs) constituting the side surface of the light-emitting layer (e.g., the blue light-emitting layer 31B) among the multiple quantum dots (QDs) contained in the light-emitting layer (e.g., the blue light-emitting layer 31B). In the present embodiment, the case is explained as an example in which the blue light-emitting layer 31B includes the upper end portion 31BET of the blue light-emitting layer 31B, the right end portion 31BER of the blue light-emitting layer 31B, the left end portion 31BEL of the blue light-emitting layer 31B, and the lower end portion 31BEB of the blue light-emitting layer 31B. However, the configuration is not limited thereto, and when a shape of the blue light-emitting layer 31B changes, shapes of the end portions thereof also change.

As illustrated in FIGS. 3 and 4, the number of the first ligands, which are at least one type of ligand selected from a ligand being a halogen atom and a ligand being a sulfur atom, contained per unit volume in the first region 31BR1 of the blue light-emitting layer 31B is greater than the number of the first ligands contained per unit volume in the second region 31BR2 of the blue light-emitting layer 31B. Note that the unit volume of the light-emitting layer (e.g., the blue light-emitting layer 31B) means part of the light-emitting layer (e.g., the blue light-emitting layer 31B) having a size of 1 μm (thickness)×1 μm (width)×1 μm (length).

For example, an organic ligand such as an acid (—COOH) or a thiol (—SH) has a weaker coordination force to a quantum dot (QD) than the first ligand, which is at least one type of ligand selected from a ligand being a halogen atom and a ligand being a sulfur atom, and is easily detached from the quantum dot (QD). Therefore, when impurities enter from the end portion of the light-emitting layer containing quantum dots (QDs) with organic ligands, the organic ligands may be detached from the quantum dots (QDs) and the quantum dots (QDs) may not be protected from the impurities. The quantum dots (QDs) then deteriorate and become non-emissive.

In the case of the blue light-emitting layer 31B illustrated in FIGS. 3 and 4, the number of the first ligands contained per unit volume in the first region 31BR1 of the blue light-emitting layer 31B is greater than the number of the first ligands contained per unit volume in the second region 31BR2 of the blue light-emitting layer 31B. That is, since the first ligands, which are at least one type of ligand selected from a ligand being a halogen atom and a ligand being a sulfur atom having a strong coordination force, are excessively coordinated to the quantum dots (QDs) in the first region 31BR1 of the blue light-emitting layer 31B, the quantum dots (QDs) can be protected from impurities even when the impurities penetrate into the quantum dots (QDs) in the first region 31BR1 of the blue light-emitting layer 31B. On the other hand, when the first ligands are excessively coordinated, the quantum dots (QDs) aggregate with each other and unevenness of the surface of the light-emitting layer increases, causing problems such as generation of leakage current. Therefore, by limiting excessive coordination of the first ligands to the first region 31BR1 (peripheral portion) of the blue light-emitting layer 31B, it is possible to both ensure light-emitting characteristics of the blue light-emitting element 5B including the blue light-emitting layer 31B and protect the quantum dots (QDs) in the first region 31BR1 of the blue light-emitting layer 31B, that is, ensure reliability.

When the blue light-emitting layer 31B illustrated in FIGS. 3 and 4 contains at least some amounts of second ligands other than the first ligands as in the present embodiment, a ratio of the number of the first ligands in the first region 31BR1 (peripheral portion) of the blue light-emitting layer 31B to a total number of ligands in the first region 31BR1 of the blue light-emitting layer 31B obtained by combining the number of the first ligands in the first region 31BR1 of the blue light-emitting layer 31B and the number of the second ligands in the first region 31BR1 of the blue light-emitting layer 31B is greater than a ratio of the number of the first ligands in the second region 31BR2 (central portion) of the blue light-emitting layer 31B to a total number of ligands in the second region 31BR2 of the blue light-emitting layer 31B obtained by combining the number of the first ligands in the second region 31BR2 of the blue light-emitting layer 31B and the number of the second ligands in the second region 31BR2 of the blue light-emitting layer 31B. That is, since the first ligands, which are at least one type of ligand selected from a ligand being a halogen atom and a ligand being a sulfur atom having a strong coordination force, are excessively coordinated to the quantum dots (QDs) in the first region 31BR1 of the blue light-emitting layer 31B, the quantum dots (QDs) can be protected from impurities even when the impurities penetrate into the quantum dots (QDs) in the first region 31BR1 of the blue light-emitting layer 31B. On the other hand, when the first ligands are excessively coordinated, the quantum dots (QDs) aggregate with each other and unevenness of the surface of the light-emitting layer increases, causing problems such as generation of leakage current. Therefore, by limiting excessive coordination of the first ligands to the first region 31BR1 (peripheral portion) of the blue light-emitting layer 31B, it is possible to both ensure light-emitting characteristics of the blue light-emitting element 5B including the blue light-emitting layer 31B and protect the quantum dots (QDs) in the first region 31BR1 of the blue light-emitting layer 31B, that is, ensure reliability.

In the present embodiment, as illustrated in FIG. 4, a case will be explained as an example in which the red light-emitting layer 31R included in the red light-emitting element 5R contains at least some amounts of first ligands, which are at least one type of ligand selected from a ligand being a halogen atom and a ligand being a sulfur atom, and includes the first region 31RR1, which is a partial region of the red light-emitting layer 31R, including all of an upper end portion 31RET of the red light-emitting layer 31R, a right end portion 31RER of the red light-emitting layer 31R, a left end portion 31REL of the red light-emitting layer 31R, and a lower end portion 31REB of the red light-emitting layer 31R, which are end portions of the red light-emitting layer 31R, and the second region 31RR2 other than the first region 31RR1, that is, the second region 31RR2 of the red light-emitting layer 31R is surrounded by the first region 31RR1 of the red light-emitting layer 31R. But the configuration is not limited thereto. As in the blue light-emitting layer 31B, since the first ligands, which are at least one type of ligand selected from a ligand being a halogen atom and a ligand being a sulfur atom having a strong coordination force, are excessively coordinated to the quantum dots (QDs) in the first region 31RR1 of the red light-emitting layer 31R, the quantum dots (QDs) can be protected from impurities even when the impurities penetrate into the quantum dots (QDs) in the first region 31RR1 of the red light-emitting layer 31R. On the other hand, when the first ligands are excessively coordinated, the quantum dots (QDs) aggregate with each other and unevenness of the surface of the light-emitting layer increases, causing problems such as generation of leakage current. Therefore, by limiting excessive coordination of the first ligands to the first region 31RR1 (peripheral portion) of the red light-emitting layer 31R, it is possible to both ensure light-emitting characteristics of the red light-emitting element 5R including the red light-emitting layer 31R and protect the quantum dots (QDs) in the first region 31RR1 of the red light-emitting layer 31R, that is, ensure reliability.

In the present embodiment, as illustrated in FIG. 4, a case will be explained as an example in which the green light-emitting layer 31G included in the green light-emitting element 5G contains at least some amounts of first ligands, which are at least one type of ligand selected from a ligand being a halogen atom and a ligand being a sulfur atom, and includes the first region 31GR1, which is a partial region of the green light-emitting layer 31G, including all of an upper end portion 31GET of the green light-emitting layer 31G, a right end portion 31GER of the green light-emitting layer 31G, a left end portion 31GEL of the green light-emitting layer 31G, and a lower end portion 31GEB of the green light-emitting layer 31G, which are end portions of the green light-emitting layer 31G, and the second region 31GR2 other than the first region 31GR1, that is, the second region 31GR2 of the green light-emitting layer 31G is surrounded by the first region 31GR1 of the green light-emitting layer 31G. But the configuration is not limited thereto. As in the blue light-emitting layer 31B and the red light-emitting layer 31R, since the first ligands, which are at least one type of ligand selected from a ligand being a halogen atom and a ligand being a sulfur atom having a strong coordination force, are excessively coordinated to the quantum dots (QDs) in the first region 31GR1 of the green light-emitting layer 31G, the quantum dots (QDs) can be protected from impurities even when the impurities penetrate into the quantum dots (QDs) in the first region 31GR1 of the green light-emitting layer 31G. On the other hand, when the first ligands are excessively coordinated, the quantum dots (QDs) aggregate with each other and unevenness of the surface of the light-emitting layer increases, causing problems such as generation of leakage current. Therefore, by limiting excessive coordination of the first ligands to the first region 31GR1 (peripheral portion) of the green light-emitting layer 31G, it is possible to both ensure light-emitting characteristics of the green light-emitting element 5G including the green light-emitting layer 31G and protect the quantum dots (QDs) in the first region 31GR1 of the green light-emitting layer 31G, that is, ensure reliability.

In the present embodiment, as illustrated in FIG. 4, the first ligands, which are at least one type of ligand selected from a ligand being a halogen atom and a ligand being a sulfur atom, are contained only in the first region 31RR1 of the red light-emitting layer 31R included in the red light-emitting element 5R, only in the first region 31GR1 of the green light-emitting layer 31G included in the green light-emitting element 5G, and only in the first region 31BR1 of the blue light-emitting layer 31B included in the blue light-emitting element 5B. Therefore, the first ligands are not contained in the second region 31RR2 of the red light-emitting layer 31R included in the red light-emitting element 5R, the second region 31GR2 of the green light-emitting layer 31G included in the green light-emitting element 5G, and the second region 31BR2 of the blue light-emitting layer 31B included in the blue light-emitting element 5B. Accordingly, in each of the red light-emitting element 5R, the green light-emitting element 5G, and the blue light-emitting element 5B, it is possible to more reliably achieve both ensuring light-emitting characteristics and ensuring reliability. However, the configuration is not limited thereto, and the first ligands may be contained in the first region 31RR1 and the second region 31RR2 of the red light-emitting layer 31R included in the red light-emitting element 5R, the first region 31GR1 and the second region 31GR2 of the green light-emitting layer 31G included in the green light-emitting element 5G, and the first region 31BR1 and the second region 31BR2 of the blue light-emitting layer 31B included in the blue light-emitting element 5B.

In the present embodiment, each of the red light-emitting layer 31R included in the red light-emitting element 5R, the green light-emitting layer 31G included in the green light-emitting element 5G, and the blue light-emitting layer 31B included in the blue light-emitting element 5B contains the organic ligands as the second ligands other than the first ligands in the first region and the second region. With such a configuration, aggregation of quantum dots (QDs) in the first region and the second region can be suppressed, and the light-emitting characteristics of the red light-emitting element 5R, the green light-emitting element 5G, and the blue light-emitting element 5B can be improved.

Further, in the present embodiment, in each of the red light-emitting layer 31R included in the red light-emitting element 5R, the green light-emitting layer 31G included in the green light-emitting element 5G, and the blue light-emitting layer 31B included in the blue light-emitting element 5B, the number of the organic ligands, which are the second ligands, contained per unit volume in the second region is greater than the number of organic ligands, which are the second ligands, contained per unit volume in the first region. With such a configuration, the light-emitting characteristics of the red light-emitting element 5R, the green light-emitting element 5G, and the blue light-emitting element 5B can be improved while suppressing deterioration in reliability thereof.

Further, in each of the red light-emitting layer 31R included in the red light-emitting element 5R, the green light-emitting layer 31G included in the green light-emitting element 5G, and the blue light-emitting layer 31B included in the blue light-emitting element 5B, a ratio of the number of the first ligands in the first region to a total number of ligands in the first region obtained by combining the number of the first ligands in the first region and the number of the organic ligands in the first region is preferably greater than a ratio of the number of the first ligands in the second region to a total number of ligands in the second region obtained by combining the number of the first ligands in the second region and the number of the organic ligands in the second region.

Note that the ratio of the number of the first ligands in the first region to the total number of ligands in the first region can be determined to be a ratio of the number of the first ligands to a total number of ligands per quantum dot (QD) contained in the first region, and the ratio of the number of the first ligands in the second region to the total number of ligands in the second region can be determined to be a ratio of the number of the first ligands to a total number of ligands per quantum dot (QD) contained in the second region.

In the following, when the first ligands are fluorine atoms, results of calculating the maximum ratio of the number of fluorine atoms, which are the first ligands, in the second region (central portion), to the total number of ligands in the second region, at which aggregation of quantum dots (QDs) can be prevented in the second region, will be shown.

When a particle diameter of the quantum dots (QDs) contained in the first region (peripheral portion) and the second region (central portion) is 3 nm, a surface area of the quantum dots (QDs) is 28.26 nm² (=4π×1.5 nm×1.5 nm). A diameter of a fluorine atom, which is the first ligand, is calculated as twice a radius of a fluorine ion (F), and is 0.26 nm. An area occupied by one fluorine atom, which is the first ligand, is 0.053066 nm² (=π×0.13 nm×0.13 nm). The number of fluorine atoms, which are the first ligands, per quantum dot (QD) can be determined from (the surface area of a quantum dot (QD)/the area occupied by one fluorine atom), and is 533. For the number of the organic ligands per quantum dot (QD), when multiple quantum dots (QDs) are packed closely, 12 quantum dots (QDs) are closely arranged per quantum dot (QD). Since the organic ligands are easily detached due to environmental factors such as heat and a coating process, in order to prevent the aggregation of the close-packed quantum dots (QDs), assuming that it is necessary to provide at least 10 organic ligands for each of 12 quantum dots (QDs) arranged closely to each other, the number of organic ligands per quantum dot (QD) is 120. The ratio of the number of fluorine atoms, which are the first ligands, to the total number of ligands per quantum dot (QD) contained in the second region (central portion) calculated from (the number of fluorine atoms, which are the first ligands, per quantum dot (QD))/(the number of fluorine atoms, which are the first ligands, per quantum dot (QD)+the number of organic ligands per quantum dot (QD)) and is 82%. Therefore, in the second region (central portion), in order to prevent the quantum dots (QDs) from aggregating with each other, the ratio of the number of fluorine atoms, which are the first ligands, to the total number of ligands per quantum dot (QD) contained in the second region is preferably 82% or less. On the other hand, in the first region (peripheral portion), in order to strongly protect the quantum dots (QDs) even when the quantum dots (QDs) aggregate with each other, the ratio of the number of fluorine atoms, which are the first ligands, to the total number of ligands per quantum dot (QD) contained in the first region is preferably higher than 82%.

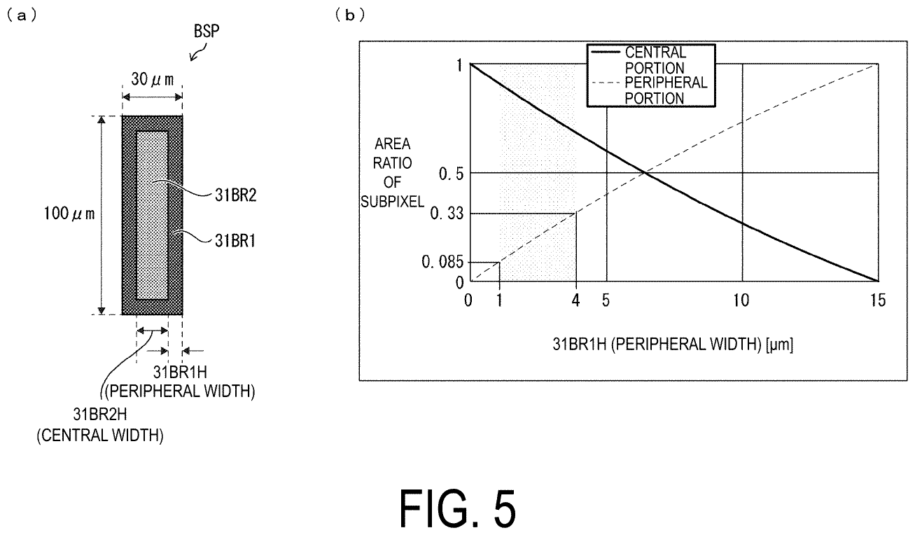

(a) of FIG. 5 is a diagram illustrating sizes of the first region (peripheral portion) 31BR1 and the second region (central portion) 31BR2 of the blue light-emitting layer 31B included in the blue light-emitting element 5B included in the blue subpixel BSP of the display device 1 according to the first embodiment, and (b) of FIG. 5 is a diagram showing a relationship between a peripheral width 31BR1H of the blue light-emitting layer 31B and a ratio of an area occupied by the first region (peripheral portion) 31BR1 and a ratio of an area occupied by the second region (central portion) 31BR2 to an area of the blue light-emitting layer 31B. Note that the peripheral width 31BR1H of the blue light-emitting layer 31B is a width of the first region (peripheral portion) 31BR1, which is the shortest distance from an edge of the blue light-emitting layer 31B to the second region (central portion) 31BR2.

Since the fluorine atoms, which are the first ligands, are contained excessively in the first region (peripheral portion) 31BR1 of the blue light-emitting layer 31B, leakage current is generated due to unevenness on the surface of the light-emitting layer caused by aggregation between the quantum dots (QDs). Since the leakage current is proportional to the area of the first region (peripheral portion) 31BR1 of the blue light-emitting layer 31B, the light-emitting characteristics of the entire blue light-emitting layer 31B can be maintained by setting the ratio of the area of the first region (peripheral portion) 31BR1 to the area of the blue light-emitting layer 31B to about 33% or less. As illustrated in (a) of FIG. 5, when the area of the blue light-emitting layer 31B is 3000 μm² (=100 μm×30 μm), the peripheral width 31BR1H of the blue light-emitting layer 31B is preferably 4 μm or less, and when the peripheral width 31BR1H is 4 μm, the area of the first region (peripheral portion) 31BR1 is 976 μm² (=4 μm×100 μm+4 μm×100 μm+4 μm×22 μm+4 μm×22 μm). The ratio of the area of the first region (peripheral portion) 31BR1 to the area of the blue light-emitting layer 31B is 0.33 (33%) from 976 μm²/3000 μm². On the other hand, a lower limit value of the peripheral width 31BR1H of the blue light-emitting layer 31B is 1 μm in consideration of ease of manufacturing, and the peripheral width 31BR1H of the blue light-emitting layer 31B is preferably 1 μm or more. When the peripheral width 31BR1H of the blue light-emitting layer 31B is 1 μm, the area of the first region (peripheral portion) 31BR1 is 256 μm² (=1 μm×100 μm+1 μm×100 μm+1 μm×28 μm+1 μm×28 μm). The ratio of the area of the first region (peripheral portion) 31BR1 to the area of the blue light-emitting layer 31B is 0.085 (8.5%) from 256 μm²/3000 μm².

From the above, as shown in (b) of FIG. 5, the ratio of the area of the first region (peripheral portion) 31BR1 to the area of the blue light-emitting layer 31B is preferably from 8.5% to 33%.

Although the blue light-emitting layer 31B is described above as an example, the same applies to the red light-emitting layer 31R and the green light-emitting layer 31G, and thus the description thereof is omitted here.

As described above, each of the red light-emitting element 5R including the red light-emitting layer 31R, the green light-emitting element 5G including the green light-emitting layer 31G, and the blue light-emitting element 5B including the blue light-emitting layer 31B can both protect the quantum dots in the peripheral portion of the light-emitting layer, that is, ensure reliability, and ensure light-emitting characteristics of the light-emitting layer. In addition, the display device 1 including the red light-emitting element 5R, the green light-emitting element 5G, and the blue light-emitting element 5B can also both protect the quantum dots in the peripheral portion of the light-emitting layer, that is, ensure reliability, and ensure light-emitting characteristics of the light-emitting layer.

The red light-emitting element 5R, the green light-emitting element 5G, and the blue light-emitting element 5B are included in the display device 1 descried above. A method of manufacturing the red light-emitting element 5R includes a first electrode forming process of forming the first electrode 22, a red light-emitting layer forming process of forming the red light-emitting layer 31R on the first electrode 22, and a second electrode forming process of forming the second electrode 25 on the red light-emitting layer 31R, a method of manufacturing the green light-emitting element 5G includes a first electrode forming process of forming the first electrode 22, a green light-emitting layer forming process of forming the green light-emitting layer 31G on the first electrode 22, and a second electrode forming process of forming the second electrode 25 on the green light-emitting layer 31G, and a method of manufacturing the blue light-emitting element 5B includes a first electrode forming process of forming the first electrode 22, a blue light-emitting layer forming process of forming the blue light-emitting layer 31B on the first electrode 22, and a second electrode forming process of forming the second electrode 25 on the blue light-emitting layer 31B. Note that the first electrode 22 of the red light-emitting element 5R, the first electrode 22 of the green light-emitting element 5G, and the first electrode 22 of the blue light-emitting element 5B can be formed in one first electrode forming process, and the second electrode 25 of the red light-emitting element 5R, the second electrode 25 of the green light-emitting element 5G, and the second electrode 25 of the blue light-emitting element 5B can also be formed in one second electrode forming process.

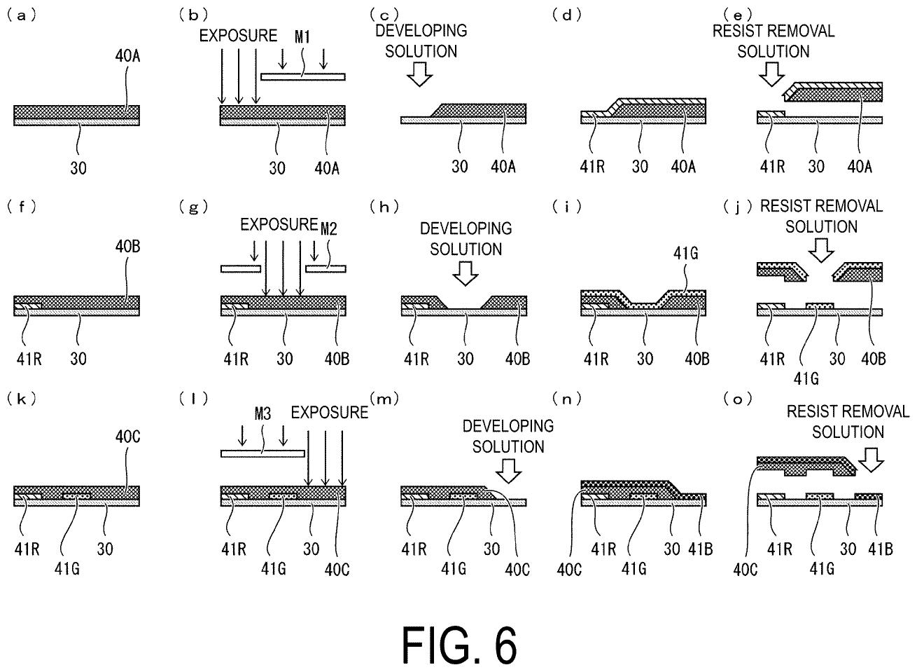

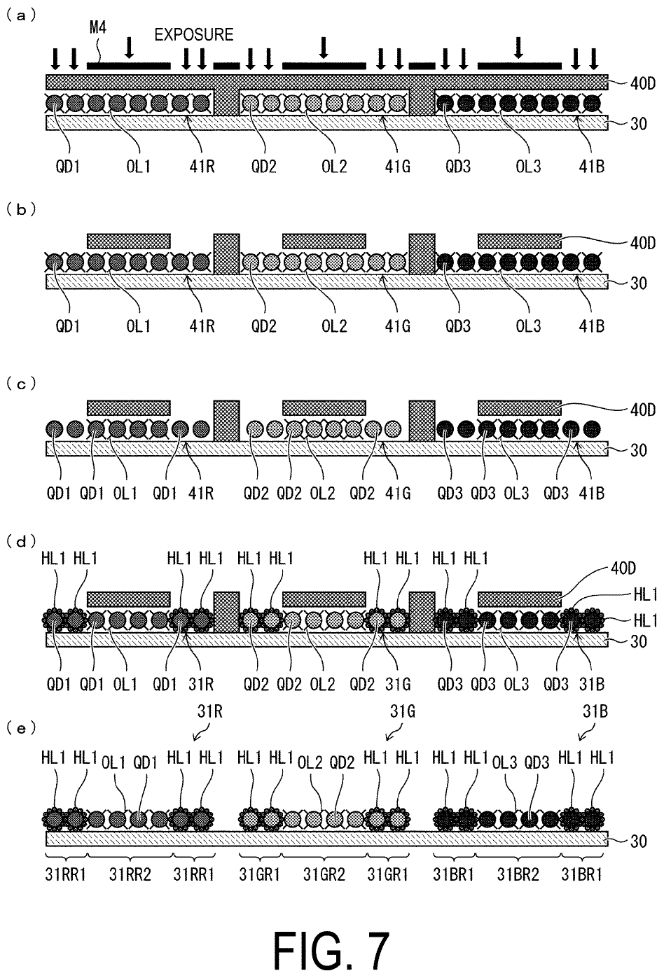

In the following, with reference to FIGS. 6 and 7, the red light-emitting layer forming process of forming the red light-emitting layer 31R, the green light-emitting layer forming process of forming the green light-emitting layer 31G, and the blue light-emitting layer forming process of forming the blue light-emitting layer 31B will be described.

(a) to (o) of FIG. 6 are diagrams illustrating an example of steps of a process of forming quantum dot layers, which is part of a process of forming the light-emitting layers included in the light-emitting elements included in the respective subpixels of the display device 1 according to the first embodiment, by a lift-off method. In (a) to (o) of FIG. 6, the first electrodes 22 included in the respective color light-emitting elements are not illustrated.

A patterning process of a red light-emitting quantum dot layer 41R, a green light-emitting quantum dot layer 41G, and a blue light-emitting quantum dot layer 41B using a lift-off method includes a step of forming a first photosensitive resin layer 40A on the hole transport layer 30 illustrated in (a) of FIG. 6, a step of exposing the first photosensitive resin layer 40A using a mask M1 illustrated in (b) of FIG. 6, a step of developing using a developing solution illustrated in (c) of FIG. 6 to form an opening in the first photosensitive resin layer 40A, a step of obtaining the red light-emitting quantum dot layer 41R by applying and heat-treating a solution containing red light-emitting quantum dots illustrated in (d) of FIG. 6, and a step of obtaining the patterned red light-emitting quantum dot layer 41R by removing the first photosensitive resin layer 40A using a resist removal solution illustrated in (e) of FIG. 6. The patterning process of the red light-emitting quantum dot layer 41R, the green light-emitting quantum dot layer 41G, and the blue light-emitting quantum dot layer 41B using a lift-off method further includes a step of forming a second photosensitive resin layer 40B on the red light-emitting quantum dot layer 41R and the hole transport layer 30 illustrated in (f) of FIG. 6, a step of exposing the second photosensitive resin layer 40B using a mask M2 illustrated in (g) of FIG. 6, a step of developing using a developing solution illustrated in (h) of FIG. 6 to form an opening in the second photosensitive resin layer 40B, a step of obtaining the green light-emitting quantum dot layer 41G by applying and heat-treating a solution containing green light-emitting quantum dots illustrated in (i) of FIG. 6, and a step of obtaining the patterned green light-emitting quantum dot layer 41G by removing the second photosensitive resin layer 40B using a resist removal solution illustrated in (j) of FIG. 6. The patterning process of the red light-emitting quantum dot layer 41R, the green light-emitting quantum dot layer 41G, and the blue light-emitting quantum dot layer 41B using a lift-off method further includes a step of forming a third photosensitive resin layer 40C on the red light-emitting quantum dot layer 41R, the green light-emitting quantum dot layer 41G, and the hole transport layer 30 illustrated in (k) of FIG. 6, a step of exposing the third photosensitive resin layer 40C using a mask M3 illustrated in (1) of FIG. 6, a step of developing using a developing solution illustrated in (m) of FIG. 6 to form an opening in the third photosensitive resin layer 40C, a step of obtaining the blue light-emitting quantum dot layer 41B by applying and heat-treating a solution containing blue light-emitting quantum dots illustrated in (n) of FIG. 6, and a step of obtaining the patterned blue light-emitting quantum dot layer 41B by removing the third photosensitive resin layer 40C using a resist removal solution illustrated in (o) of FIG. 6. Note that, as the resist removal solutions illustrated in (e), (j), and (o) of FIG. 6, for example, PGMEA or the like can be used, but the resist removal solution is not limited thereto. In the present embodiment, a case is described as an example in which the red light-emitting quantum dot layer 41R, the green light-emitting quantum dot layer 41G, and the blue light-emitting quantum dot layer 41B are formed in this order. However, formation order is not limited thereto and any color of quantum dot layer may be formed first.

(a), (b), (c), (d), and (e) of FIG. 7 are diagrams illustrating remaining steps of the process of forming the light-emitting layer performed after the process of forming the quantum dot layer illustrated in FIG. 6. In (a) to (e) of FIG. 7, the first electrodes 22 included in the respective color light-emitting elements are not illustrated.

As illustrated in (a) of FIG. 7, red light-emitting quantum dots QD1 contained in the red light-emitting quantum dot layer 41R are provided with organic ligands OL1, green light-emitting quantum dots QD2 contained in the green light-emitting quantum dot layer 41G are provided with organic ligands OL2, and blue light-emitting quantum dots QD3 contained in the blue light-emitting quantum dot layer 41B are provided with organic ligands OL3. This is because, in the present embodiment, in the step of obtaining the red light-emitting quantum dot layer 41R illustrated in (d) of FIG. 6, the red light-emitting quantum dot layer 41R is formed by applying and heat-treating the solution containing the red light-emitting quantum dots QD1 and the organic ligands OL1, in the step of obtaining the green light-emitting quantum dot layer 41G illustrated in (i) of FIG. 6, the green light-emitting quantum dot layer 41G is formed by applying and heat-treating the solution containing the green light-emitting quantum dots QD2 and the organic ligands OL2, and, in the step of obtaining the blue light-emitting quantum dot layer 41B illustrated in (n) of FIG. 6, the blue light-emitting quantum dot layer 41B is formed by applying and heat-treating the solution containing the blue light-emitting quantum dots QD3 and the organic ligands OL3. By using such a method, the organic ligands can be incorporated without separately providing steps of incorporating the organic ligands. Note that the organic ligand OL1, the organic ligand OL2, and the organic ligand OL3 may be the same organic ligand, or at least one of the organic ligand OL1, the organic ligand OL2, and the organic ligand OL3 may be a different organic ligand.

Without being limited to this method, for example, in the step of obtaining the red light-emitting quantum dot layer 41R illustrated in (d) of FIG. 6, the red light-emitting quantum dot layer 41R may be formed by applying and heat-treating a solution containing the red light-emitting quantum dots QD1 and the first ligands described above, in the step of obtaining the green light-emitting quantum dot layer 41G illustrated in (i) of FIG. 6, the green light-emitting quantum dot layer 41G may be formed by applying and heat-treating a solution containing the green light-emitting quantum dots QD2 and the first ligands described above, and in the step of obtaining the blue light-emitting quantum dot layer 41B illustrated in (n) of FIG. 6, the blue light-emitting quantum dot layer 41B may be formed by applying and heat-treating a solution containing the blue light-emitting quantum dots QD3 and the first ligands described above. By using such a method, the quantum dot layer containing the first ligands can be formed during the quantum dot layer forming process illustrated in FIG. 6.

As illustrated in (a) and (b) of FIG. 7, a photosensitive resin layer forming step is performed in which a photosensitive resin layer 40D is formed on entire surfaces of the red light-emitting quantum dot layer 41R, the green light-emitting quantum dot layer 41G, the blue light-emitting quantum dot layer 41B, and the hole transport layer 30, and then a patterning step of the photosensitive resin layer 40D is performed in which by exposing and developing the photosensitive resin layer 40D using a mask M4, the photosensitive resin layer 40D on the first region, which is a partial region of the red light-emitting quantum dot layer 41R including at least part of the end portion of the red light-emitting quantum dot layer 41R, the photosensitive resin layer 40D on the first region, which is a partial region of the green light-emitting quantum dot layer 41G including at least part of the end portion of the green light-emitting quantum dot layer 41G, and the photosensitive resin layer 40D on the first region, which is a partial region of the blue light-emitting quantum dot layer 41B including at least part of the end portion of the blue light-emitting quantum dot layer 41B, are removed, while the photosensitive resin layer 40D on the second region of the red light-emitting quantum dot layer 41R other than the first region of the red light-emitting quantum dot layer 41R, the photosensitive resin layer 40D on the second region of the green light-emitting quantum dot layer 41G other than the first region of the green light-emitting quantum dot layer 41G, and the photosensitive resin layer 40D on the second region of the blue light-emitting quantum dot layer 41B other than the first region of the blue light-emitting quantum dot layer 41B are left.

In the present embodiment, as illustrated in (b) of FIG. 7, in the patterning step of the photosensitive resin layer 40D, the photosensitive resin layer 40D on the first region, which is a partial region of the red light-emitting quantum dot layer 41R including the entire end portion of the red light-emitting quantum dot layer 41R, the photosensitive resin layer 40D on the first region, which is a partial region of the green light-emitting quantum dot layer 41G including the entire end portion of the green light-emitting quantum dot layer 41G, and the photosensitive resin layer 40D on the first region, which is a partial region of the blue light-emitting quantum dot layer 41B including the entire end portion of the blue light-emitting quantum dot layer 41B, are removed, while the photosensitive resin layer 40D on the second region of the red light-emitting quantum dot layer 41R other than the first region of the red light-emitting quantum dot layer 41R, the photosensitive resin layer 40D on the second region of the green light-emitting quantum dot layer 41G other than the first region of the green light-emitting quantum dot layer 41G, and the photosensitive resin layer 40D on the second region of the blue light-emitting quantum dot layer 41B other than the first region of the blue light-emitting quantum dot layer 41B are left. That is, the photosensitive resin layer 40D is removed in a frame shape, but the removing manner is not limited thereto.

Then, as illustrated in (c) of FIG. 7, after the patterning step of the photosensitive resin layer 40D described above and before a step of incorporating the first ligands HL1 illustrated in (d) of FIG. 7, a washing step of removing the organic ligands OL1, OL2, and OL3 is performed. In this washing step, at least some of the organic ligands OL1 in the first region of the red light-emitting quantum dot layer 41R, at least some of the organic ligands OL2 in the first region of the green light-emitting quantum dot layer 41G, and at least some of the organic ligands OL3 in the first region of the blue light-emitting quantum dot layer 41B are removed using an alcohol solution. Note that as the alcohol solution, for example, methanol or ethanol can be suitably used, but the alcohol solution is not limited thereto. Thus, by performing the washing step of removing the organic ligands OL1, OL2, and OL3 in the first region, the ratio of the organic ligands OL1, OL2, and OL3 to the first ligands HL1 in the first region can be easily adjusted.

Thereafter, as illustrated in (d) of FIG. 7, the step of incorporating the first ligands HL1 into the red light-emitting quantum dot layer 41R, the green light-emitting quantum dot layer 41G, and the blue light-emitting quantum dot layer 41B is performed in which a layer obtained by a solution containing the first ligands HL1, which are at least one type of ligand selected from a ligand being a halogen atom and a ligand being a sulfur atom, is formed on the first region of the red light-emitting quantum dot layer 41R, the first region of the green light-emitting quantum dot layer 41G, and the first region of the blue light-emitting quantum dot layer 41B. After the step of incorporating the first ligands HL1, a step of removing solvents (e.g., a heat treatment step or a drying step) may be performed as necessary. Note that the solution containing the first ligands HL1 contains the first ligands HL1 and a solvent that dissolves or disperses the first ligands HL1. That is, the solution containing the first ligands HL1 contains cations corresponding to anions such as F⁻, Cl⁻, Br⁻, I⁻, or S²⁻ that dissociate in the solvent. Examples of solvents that can be used to dissolve or disperse the first ligands HL1 include dimethyl sulfoxide (DMSO), methanol, and ethanol. A contained amount of the first ligands HL1 in the solution is within a range in which the first ligands HL1 can be dissolved or dispersed in the solvent to be used, and can be appropriately determined in consideration of an amount of the first ligands HL1 to be incorporated. In the present embodiment, as the first ligands HL1, fluorine atoms, which are ligands including halogen atoms, are used, and a solution containing fluorine atoms is used as the solution containing the first ligands HL1. Examples of solutions containing the first ligands HL1 that can be used include solutions in which F⁻ and Zn²⁺ are generated by dissolving zinc fluoride (ZnF₂) in ethanol, and solutions in which F and (CH₃CH₂CH₂CH₂)₄N⁺ are generated by dissolving tetrabutylammonium fluoride (TBAF) in ethanol.

Thereafter, as illustrated in (e) of FIG. 7, after the step of incorporating the first ligands HL1, a photosensitive resin layer removal step of removing the photosensitive resin layer 40D is performed to form the red light-emitting layer 31R including the first region 31RR1 and the second region 31RR2, the green light-emitting layer 31G including the first region 31GR1 and the second region 31GR2, and the blue light-emitting layer 31B including the first region 31BR1 and the second region 31BR2 on the hole transport layer 30.

According to the above-described manufacturing method, since the steps illustrated in (a) to (e) of FIG. 7 are performed for all of the red light-emitting quantum dot layer 41R, the green light-emitting quantum dot layer 41G, and the blue light-emitting quantum dot layer 41B formed by the method illustrated in FIG. 6, the number of manufacturing steps can be reduced.

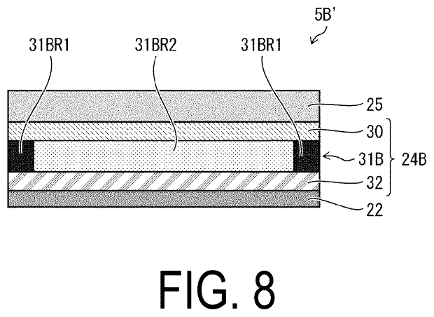

FIG. 8 is a cross-sectional view illustrating a schematic configuration of a blue light-emitting element 5B′, which is a modification of the blue light-emitting element 5B included in the display device 1 according to the first embodiment illustrated in FIG. 3.

As illustrated in FIG. 8, the blue light-emitting element 5B′ includes the first electrode 22 and the second electrode 25, and the function layer 24B placed between the first electrode 22 and the second electrode 25 and including at least the blue light-emitting layer 31B containing quantum dots (QDs). The blue light-emitting element 5B′ is different from the blue light-emitting element 5B illustrated in FIG. 3 in that the function layer 24B is configured by layering the electron transport layer 32, the blue light-emitting layer 31B, and the hole transport layer 30 in order from the first electrode 22 side.

The blue light-emitting element 5B′ illustrated in FIG. 8 may be a top-emitting type or a bottom-emitting type. The blue light-emitting element 5B′ has an inversely layered structure in which a cathode serving as the first electrode 22, the electron transport layer 32, the blue light-emitting layer 31B, the hole transport layer 30, and an anode serving as the second electrode 25 are formed in this order, and therefore the anode serving as the second electrode 25 is arranged as an upper layer above the cathode serving as the first electrode 22. Thus, in order to achieve a top-emitting type light-emitting element, the cathode serving as the first electrode 22 may be formed of an electrode material that reflects visible light, and the anode serving as the second electrode 25 may be formed of an electrode material that transmits visible light, and in order to achieve a bottom-emitting type light-emitting element, the cathode serving as the first electrode 22 may be formed of an electrode material that transmits visible light, and the anode serving as the second electrode 25 may be formed of an electrode material that reflects visible light.

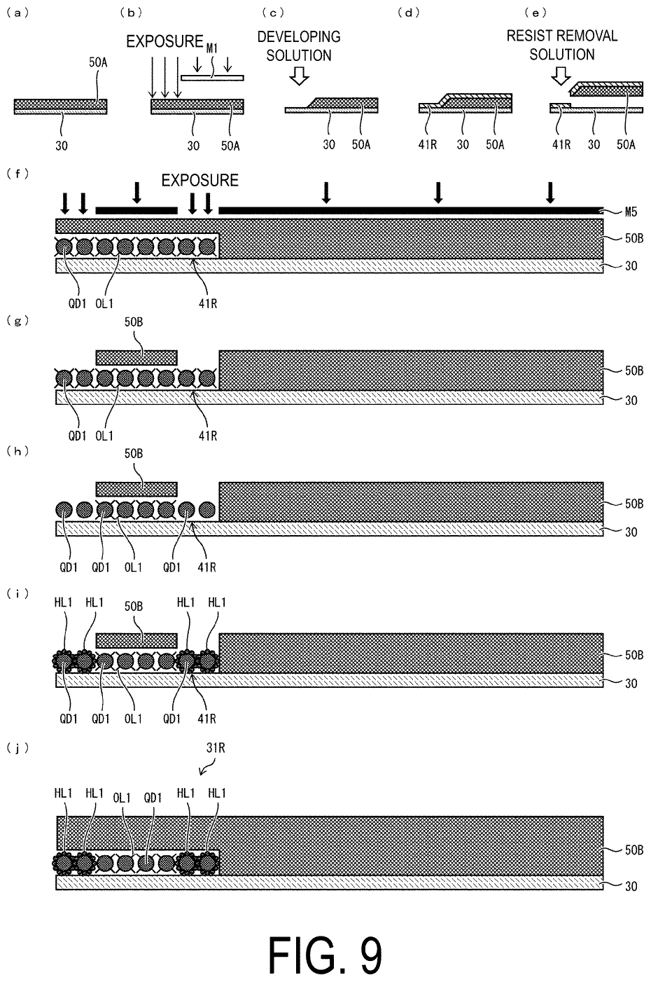

(a) to (j) of FIG. 9 illustrate some steps of still another process of forming the red light-emitting layer 31R, the green light-emitting layer 31G, and the blue light-emitting layer 31B included in the display device 1 according to the first embodiment.

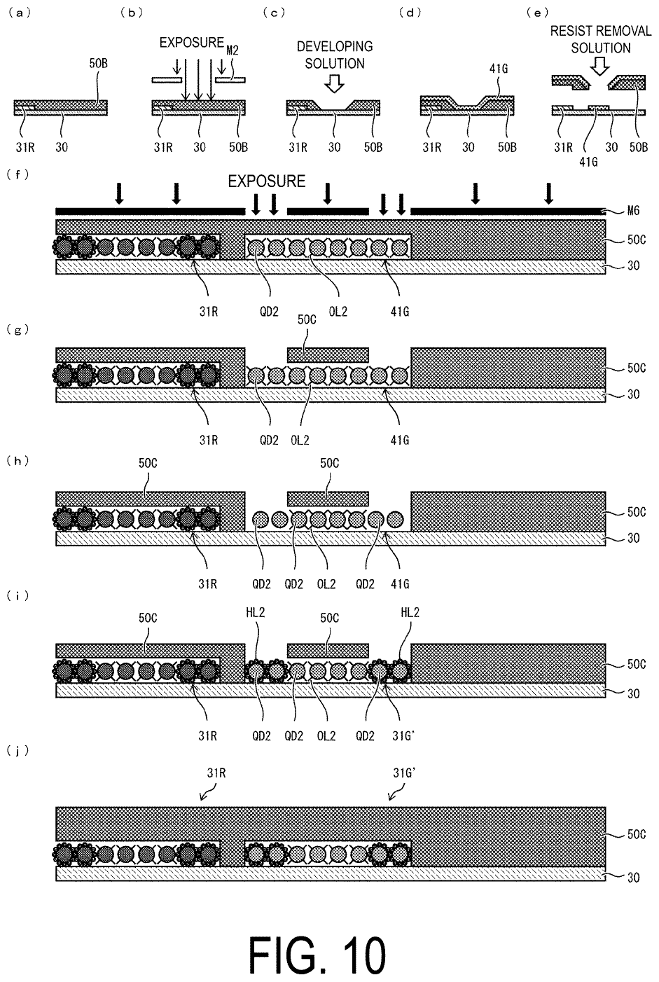

(a) to (j) of FIG. 10 illustrate subsequent steps of the steps illustrated in (a) to (j) of FIG. 9.

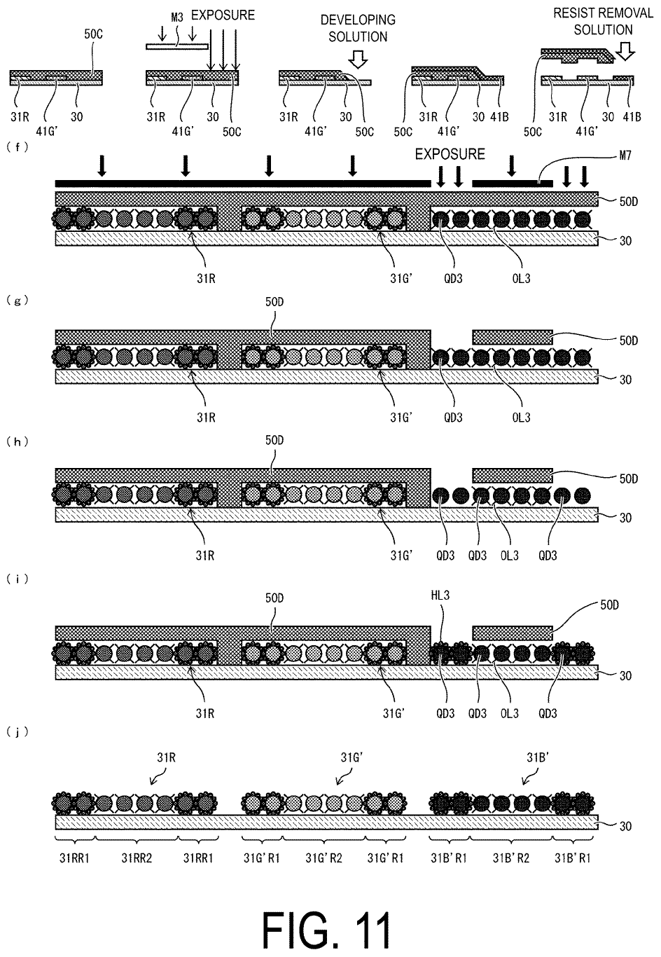

(a) to (j) of FIG. 11 illustrate subsequent steps of the steps illustrated in (a) to (j) of FIG. 10.

In (a) to (j) of FIG. 9, (a) to (j) of FIG. 10, and (a) to (j) of FIG. 11, the first electrodes 22 included in the respective color light-emitting elements are not illustrated.

A patterning process of the red light-emitting quantum dot layer 41R using a lift-off method includes a step of forming a first photosensitive resin layer 50A on the hole transport layer 30 illustrated in (a) of FIG. 9, a step of exposing the first photosensitive resin layer 50A using the mask M1 illustrated in (b) of FIG. 9, a step of developing using a developing solution illustrated in (c) of FIG. 9 to form an opening in the first photosensitive resin layer 50A, a step of obtaining the red light-emitting quantum dot layer 41R by applying and heat-treating a solution containing red light-emitting quantum dots illustrated in (d) of FIG. 9, and a step of obtaining the patterned red light-emitting quantum dot layer 41R by removing the first photosensitive resin layer 50A using a resist removal solution illustrated in (e) of FIG. 9. Here, a case will be described as an example in which the red light-emitting quantum dot layer 41R is patterned using the lift-off method, but the method is not limited thereto as long as the red light-emitting quantum dot layer 41R can be formed on some first electrodes 22 among the multiple first electrodes 22.

As illustrated in (f) and (g) of FIG. 9, a photosensitive resin layer forming step is performed in which a second photosensitive resin layer 50B is formed on entire surfaces of the red light-emitting quantum dot layer 41R and the hole transport layer 30, and then a patterning step of the second photosensitive resin layer 50B is performed in which by exposing and developing the second photosensitive resin layer 50B using a mask M5, the second photosensitive resin layer 50B on the first region, which is a partial region of the red light-emitting quantum dot layer 41R including at least part of the end portion of the red light-emitting quantum dot layer 41R, is removed, while the second photosensitive resin layer 50B on the second region of the red light-emitting quantum dot layer 41R other than the first region of the red light-emitting quantum dot layer 41R is left.

In the present embodiment, as illustrated in (g) of FIG. 9, in the patterning step of the second photosensitive resin layer 50B, the second photosensitive resin layer 50B on the first region, which is a partial region of the red light-emitting quantum dot layer 41R including the entire end portion of the red light-emitting quantum dot layer 41R, is removed, and the second photosensitive resin layer 50B on the second region of the red light-emitting quantum dot layer 41R other than the first region of the red light-emitting quantum dot layer 41R is left. That is, the second photosensitive resin layer 50B is removed in a frame shape, but the removing manner is not limited thereto.

Then, as illustrated in (h) of FIG. 9, after the patterning step of the second photosensitive resin layer 50B described above and before a step of incorporating the first ligands HL1 illustrated in (i) of FIG. 9, a washing step of removing the organic ligands OL1 is performed. In this washing step, at least some of the organic ligands OL1 in the first region of the red light-emitting quantum dot layer 41R are removed using an alcohol solution. Thus, by performing the washing step of removing the organic ligands OL1 in the first region of the red light-emitting quantum dot layer 41R, a ratio of the organic ligands OL1 in the first region of the red light-emitting quantum dot layer 41R to the first ligands HL1 in the red light-emitting quantum dot layer 41R can be easily adjusted.

Thereafter, as illustrated in (i) of FIG. 9, the step of incorporating the first ligands HL1 into the red light-emitting quantum dot layer 41R is performed in which a layer obtained by a solution containing the first ligands HL1, which are at least one type of ligand selected from a ligand being a halogen atom and a ligand being a sulfur atom, is formed on the first region of the red light-emitting quantum dot layer 41R to form the red light-emitting layer 31R. After the step of incorporating the first ligands HL1, a step of removing solvents (e.g., a heat treatment step or a drying step) may be performed as necessary.

Thereafter, as illustrated in (j) of FIG. 9, after the step of incorporating the first ligands HL1, by forming a photosensitive resin material on at least the first region of the red light-emitting layer 31R, a step of forming the second photosensitive resin layer 50B is performed again. In the present embodiment, by forming the photosensitive resin material not only on the first region of the red light-emitting layer 31R but also on the entire hole transport layer 30, the second photosensitive resin layer 50B is formed again, but the formation method of the photosensitive resin material is not limited thereto.

A patterning process of the green light-emitting quantum dot layer 41G using a lift-off method includes a step of forming the second photosensitive resin layer 50B again as illustrated in (j) of FIG. 9 and (a) of FIG. 10, a step of exposing the second photosensitive resin layer 50B using the mask M2 as illustrated in (b) of FIG. 10, a step of developing using a developing solution illustrated in (c) of FIG. 10 to form an opening in the second photosensitive resin layer 50B, a step of obtaining the green light-emitting quantum dot layer 41G by applying and heat-treating a solution containing green light-emitting quantum dots illustrated in (d) of FIG. 10, and a step of obtaining the patterned green light-emitting quantum dot layer 41G by removing the second photosensitive resin layer 50B using a resist removal solution illustrated in (e) of FIG. 10. Here, a case will be described as an example in which the green light-emitting quantum dot layer 41G is patterned using a lift-off method, but the method is not limited thereto as long as the green light-emitting quantum dot layer 41G can be formed on some other first electrodes 22 among the multiple first electrodes 22.

As illustrated in (f) and (g) of FIG. 10, a photosensitive resin layer forming step is performed in which a third photosensitive resin layer 50C is formed on entire surfaces of the red light-emitting layer 31R, the green light-emitting quantum dot layer 41G, and the hole transport layer 30, and then a patterning step of the third photosensitive resin layer 50C is performed in which by exposing and developing the third photosensitive resin layer 50C using a mask M6, the third photosensitive resin layer 50C on the first region, which is a partial region of the green light-emitting quantum dot layer 41G including at least part of the end portion of the green light-emitting quantum dot layer 41G, is removed, while the third photosensitive resin layer 50C on the second region of the green light-emitting quantum dot layer 41G other than the first region of the green light-emitting quantum dot layer 41G is left.

In the present embodiment, as illustrated in (g) of FIG. 10, in the patterning step of the third photosensitive resin layer 50C, the third photosensitive resin layer 50C on the first region, which is a partial region of the green light-emitting quantum dot layer 41G including the entire end portion of the green light-emitting quantum dot layer 41G, is removed, while the third photosensitive resin layer 50C on the second region of the green light-emitting quantum dot layer 41G other than the first region of the green light-emitting quantum dot layer 41G is left. That is, the third photosensitive resin layer 50C is removed in a frame shape, but the removing manner is not limited thereto.

Then, as illustrated in (h) of FIG. 10, after the patterning step of the third photosensitive resin layer 50C described above and before a step of incorporating first ligands HL2 illustrated in (i) of FIG. 10, a washing step of removing the organic ligands OL2 is performed. In this washing step, at least some of the organic ligands OL2 in the first region of the green light-emitting quantum dot layer 41G are removed using an alcohol solution. Thus, by performing the washing step of removing the organic ligands OL2 in the first region of the green light-emitting quantum dot layer 41G, a ratio of the organic ligands OL2 in the first region of the green light-emitting quantum dot layer 41G to the first ligands HL2 of the green light-emitting quantum dot layer 41G can be easily adjusted.

Thereafter, as illustrated in (i) of FIG. 10, the step of incorporating the first ligands HL2 into the green light-emitting quantum dot layer 41G is performed in which a layer obtained by a solution containing the first ligands HL2, which are at least one type of ligand selected from a ligand being a halogen atom and a ligand being a sulfur atom, is formed on the first region of the green light-emitting quantum dot layer 41G to form a green light-emitting layer 31G′. After the step of incorporating the first ligands HL2, a step of removing solvents (e.g., a heat treatment step or a drying step) may be performed as necessary. Note that in the present embodiment, the first ligands HL2 incorporated into the green light-emitting quantum dot layer 41G are a different type of ligand from the first ligands HL1 incorporated into the red light-emitting quantum dot layer 41R. Thus, by using different types of ligands, it is possible to select the most preferable type of ligand for the quantum dots contained in each color light-emitting layer.

Thereafter, as illustrated in (j) of FIG. 10, after the step of incorporating the first ligands HL2, by forming a photosensitive resin material on at least the first region of the green light-emitting layer 31G′, a step of forming the third photosensitive resin layer 50C is performed again. In the present embodiment, by forming the photosensitive resin material not only on the first region of the green light-emitting layer 31G′ but also on the entire hole transport layer 30, the third photosensitive resin layer 50C is formed again, but the formation method of the photosensitive resin material is not limited thereto.

A patterning process of the blue light-emitting quantum dot layer 41B using a lift-off method includes a step of forming the third photosensitive resin layer 50C again as illustrated in (j) of FIG. 10 and (a) of FIG. 11, a step of exposing the third photosensitive resin layer 50C using the mask M3 as illustrated in (b) of FIG. 11, a step of developing using a developing solution illustrated in (c) of FIG. 11 to form an opening in the third photosensitive resin layer 50C, a step of obtaining the blue light-emitting quantum dot layer 41B by applying and heat-treating a solution containing blue light-emitting quantum dots illustrated in (d) of FIG. 11, and a step of obtaining the patterned blue light-emitting quantum dot layer 41B by removing the third photosensitive resin layer 50C using a resist removal solution illustrated in (e) of FIG. 11. Here, a case will be described as an example in which the blue light-emitting quantum dot layer 41B is patterned using a lift-off method, but the method is not limited thereto as long as the blue light-emitting quantum dot layer 41B can be formed on still some other first electrodes 22 among the multiple first electrodes 22.

As illustrated in (f) and (g) of FIG. 11, a photosensitive resin layer forming step is performed in which a fourth photosensitive resin layer 50D is formed on entire surfaces of the red light-emitting layer 31R, the green light-emitting layer 31G′, the blue light-emitting quantum dot layer 41B, and the hole transport layer 30, and then a patterning step of the fourth photosensitive resin layer 50D is performed in which by exposing and developing the fourth photosensitive resin layer 50D using a mask M7, the fourth photosensitive resin layer 50D on the first region, which is a partial region of the blue light-emitting quantum dot layer 41B including at least part of the end portion of the blue light-emitting quantum dot layer 41B, is removed, and the fourth photosensitive resin layer 50D on the second region of the blue light-emitting quantum dot layer 41B other than the first region of the blue light-emitting quantum dot layer 41B is left.

In the present embodiment, as illustrated in (g) of FIG. 11, in the patterning step of the fourth photosensitive resin layer 50D, the fourth photosensitive resin layer 50D on the first region, which is a partial region of the blue light-emitting quantum dot layer 41B including the entire end portion of the blue light-emitting quantum dot layer 41B, is removed, while the fourth photosensitive resin layer 50D on the second region of the blue light-emitting quantum dot layer 41B other than the first region of the blue light-emitting quantum dot layer 41B is left. That is, the fourth photosensitive resin layer 50D is removed in a frame shape, but the removing manner is not limited thereto.

Then, as illustrated in (h) of FIG. 11, after the patterning step of the fourth photosensitive resin layer 50D described above and before a step of incorporating first ligands HL3 illustrated in (i) of FIG. 11, a washing step of removing the organic ligands OL3 is performed. In this washing step, at least some of the organic ligands OL3 in the first region of the blue light-emitting quantum dot layer 41B are removed using an alcohol solution. Thus, by performing the washing step of removing the organic ligands OL3 in the first region of the blue light-emitting quantum dot layer 41B, a ratio of the organic ligands OL3 in the first region of the blue light-emitting quantum dot layer 41B to the first ligands HL3 of the blue light-emitting quantum dot layer 41B can be easily adjusted.

Thereafter, as illustrated in (i) of FIG. 11, the step of incorporating the first ligands HL3 into the blue light-emitting quantum dot layer 41B is performed in which a layer obtained by a solution containing the first ligands HL3, which are at least one type of ligand selected from a ligand being a halogen atom and a ligand being a sulfur atom, is formed on the first region of the blue light-emitting quantum dot layer 41B to form a blue light-emitting layer 31B′. After the step of incorporating the first ligands HL3, a step of removing solvents (e.g., a heat treatment step or a drying step) may be performed as necessary. Note that in the present embodiment, the first ligands HL3 incorporated into the blue light-emitting quantum dot layer 41B are a different type of ligand from the first ligands HL2 incorporated into the green light-emitting quantum dot layer 41G and the first ligands HL1 incorporated into the red light-emitting quantum dot layer 41R. Thus, by using different types of ligands, it is possible to select the most preferable type of ligand for the quantum dots contained in each color light-emitting layer.

Thereafter, as illustrated in (j) of FIG. 11, after the step of incorporating the first ligands HL3, a photosensitive resin layer removal step of removing the fourth photosensitive resin layer 50D is performed to form the red light-emitting layer 31R including the first region 31RR1 and the second region 31RR2, the green light-emitting layer 31G′ including a first region 31G′R1 and a second region 31G′R2, and the blue light-emitting layer 31B′ including a first region 31B′R1 and a second region 31B′R2 on the hole transport layer 30.

In the above, a case is described as an example in which the red light-emitting layer 31R, the green light-emitting layer 31G′, and the blue light-emitting layer 31B′ are formed in this order. However, formation order is not limited thereto and any color light-emitting layer may be formed first.

Note that in the manufacturing process of the present embodiment described above, the case is described as an example in which all the photosensitive resin layers are made of a positive type photosensitive resin material in consideration of ease of peeling, but the material is not limited thereto.

### Second Embodiment

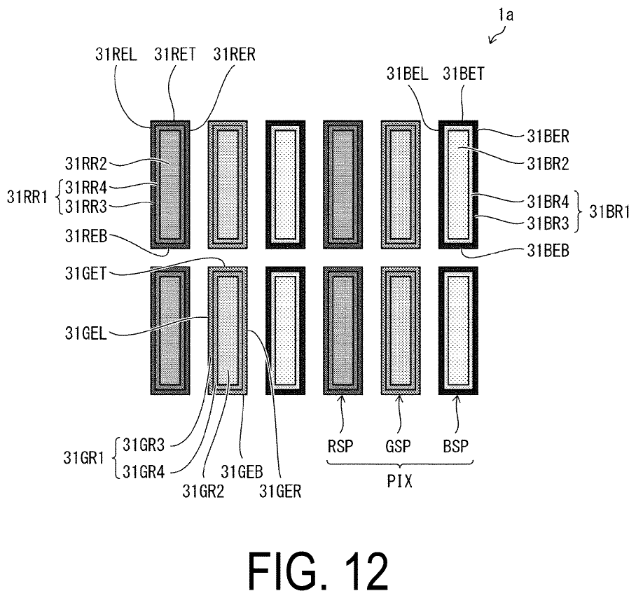

Next, a second embodiment according to the disclosure will be described with reference to FIGS. 12 to 14. A display device 1a according to the present embodiment is different from the display device 1 described in the first embodiment in that a first region of each color light-emitting layer includes multiple sub-regions. The others are as described in the first embodiment. For convenience of description, members having the same functions as those illustrated in diagrams of the first embodiment are denoted by the same reference signs, and descriptions thereof are omitted.

FIG. 12 is a plan view of a red light-emitting layer 31R included in a red light-emitting element 5R included in a red subpixel RSP, a green light-emitting layer 31G included in a green light-emitting element 5G included in a green subpixel GSP, and a blue light-emitting layer 31B included in a blue light-emitting element 5B included in a blue subpixel BSP of the display device 1a according to the second embodiment.

As illustrated in FIG. 12, a first region 31RR1 of the red light-emitting layer 31R included in the red light-emitting element 5R includes multiple sub-regions, which are a third region 31RR3 and a fourth region 31RR4. In the present embodiment, a case in which the multiple sub-regions are constituted of the third region 31RR3 and the fourth region 31RR4 is described as an example, but the multiple sub-regions are not limited thereto, and may be constituted of three or more sub-regions. The multiple sub-regions, which are two adjacent sub-regions, that is, the third region 31RR3 and the fourth region 31RR4, are the fourth region 31RR4, which is an inner sub-region located closer to a second region 31RR2, and the third region 31RR3, which is an outer sub-region located farther from the second region 31RR2, and the number of the first ligands contained per unit volume in the third region 31RR3, which is the outer sub-region, is greater than the number of the first ligands contained per unit volume in the fourth region 31RR4, which is the inner sub-region. A first region 31GR1 of the green light-emitting layer 31G included in the green light-emitting element 5G includes multiple sub-regions, which are a third region 31GR3 and a fourth region 31GR4. In the present embodiment, a case in which the multiple sub-regions are constituted of the third region 31GR3 and the fourth region 31GR4 is described as an example, but the sub-regions are not limited thereto, and may be constituted of three or more sub-regions. The multiple sub-regions, which are two adjacent sub-regions, that is, the third region 31GR3 and the fourth region 31GR4, are the fourth region 31GR4, which is an inner sub-region located closer to a second region 31GR2, and the third region 31GR3, which is an outer sub-region located farther from the second region 31GR2, and the number of the first ligands contained per unit volume in the third region 31GR3, which is the outer sub-region, is greater than the number of the first ligands contained per unit volume in the fourth region 31GR4, which is the inner sub-region. A first region 31BR1 of the blue light-emitting layer 31B included in the blue light-emitting element 5B includes multiple sub-regions, which are a third region 31BR3 and a fourth region 31BR4. In the present embodiment, a case in which the multiple sub-regions are constituted of the third region 31BR3 and the fourth region 31BR4 is described as an example, but the multiple sub-regions are not limited thereto, and may be constituted of three or more sub-regions. The multiple sub-regions, which are two adjacent sub-regions, that is, the third region 31BR3 and the fourth region 31BR4, are the fourth region 31BR4, which is an inner sub-region located closer to a second region 31BR2, and the third region 31BR3, which is an outer sub-region located farther from the second region 31BR2, and the number of the first ligands contained per unit volume in the third region 31BR3, which is the outer sub-region, is greater than the number of the first ligands contained per unit volume in the fourth region 31BR4, which is the inner sub-region. Therefore, the number of the first ligands contained per unit volume in the second region 31RR2 of the red light-emitting layer 31R is smaller than the number of the first ligands contained per unit volume in the fourth region 31RR4 of the red light-emitting layer 31R, and the number of the first ligands contained per unit volume in the fourth region 31RR4 of the red light-emitting layer 31R is smaller than the number of the first ligands contained per unit volume in the third region 31RR3 of the red light-emitting layer 31R. The number of the first ligands contained per unit volume in the second region 31GR2 of the green light-emitting layer 31G is smaller than the number of the first ligands contained per unit volume in the fourth region 31GR4 of the green light-emitting layer 31G, and the number of the first ligands contained per unit volume in the fourth region 31GR4 of the green light-emitting layer 31G is smaller than the number of the first ligands contained per unit volume in the third region 31GR3 of the green light-emitting layer 31G. The number of the first ligands contained per unit volume in the second region 31BR2 of the blue light-emitting layer 31B is smaller than the number of the first ligands contained per unit volume in the fourth region 31BR4 of the blue light-emitting layer 31B, and the number of the first ligands contained per unit volume in the fourth region 31BR4 of the blue light-emitting layer 31B is smaller than the number of the first ligands contained per unit volume in the third region 31BR3 of the blue light-emitting layer 31B. According to such a configuration, by reducing the number of the first ligands contained per unit volume in the fourth region, which is less affected by impurities or the like, than the third region, which is more affected by impurities or the like, in each color light-emitting layer, protection of the quantum dots (QDs) in the third region of each color light-emitting layer can be efficiently stronger than protection of the quantum dots (QDs) in the fourth region while reducing an amount of the first ligands compared to the case in the first embodiment described above in which the number of the first ligands contained per unit volume is equal throughout the first region.

Each of the red light-emitting layer 31R, the green light-emitting layer 31G, and the blue light-emitting layer 31B may contain at least some amounts of second ligands, which are ligands other than the first ligands, and in the present embodiment, for example, a case will be described as an example in which organic ligands being organic molecules having a certain length are used as the second ligands in order to prevent the aggregation of the quantum dots (QDs), but the second ligand is not limited thereto.

As illustrated in FIG. 12, the third region 31RR3 and the fourth region 31RR4 of the red light-emitting layer 31R are the fourth region 31RR4, which is the inner sub-region provided closer to the second region 31RR2, and the third region 31RR3, which is the outer sub-region provided farther from the second region 31RR2, and a ratio of the number of the first ligands in the third region 31RR3 to a total number of ligands in the third region 31RR3 obtained by combining the number of the first ligands in the third region 31RR3 and the number of the second ligands in the third region 31RR3 is greater than a ratio of the number of the first ligands in the fourth region 31RR4 to a total number of ligands in the fourth region 31RR4 obtained by combining the number of the first ligands in the fourth region 31RR4 and the number of the second ligands in the fourth region 31RR4. The third region 31GR3 and the fourth region 31GR4 of the green light-emitting layer 31G are the fourth region 31GR4, which is the inner sub-region provided closer to the second region 31GR2, and the third region 31GR3, which is the outer sub-region provided farther from the second region 31GR2, and a ratio of the number of the first ligands in the third region 31GR3 to a total number of ligands in the third region 31GR3 obtained by combining the number of the first ligands in the third region 31GR3 and the number of the second ligands in the third region 31GR3 is greater than a ratio of the number of the first ligands in the fourth region 31GR4 to a total number of ligands in the fourth region 31GR4 obtained by combining the number of the first ligands in the fourth region 31GR4 and the number of the second ligands in the fourth region 31GR4. The third region 31BR3 and the fourth region 31BR4 of the blue light-emitting layer 31B are the fourth region 31BR4, which is the inner sub-region provided closer to the second region 31BR2, and the third region 31BR3, which is the outer sub-region provided farther from the second region 31BR2, and a ratio of the number of the first ligands in the third region 31BR3 to a total number of ligands in the third region 31BR3 obtained by combining the number of the first ligands in the third region 31BR3 and the number of the second ligands in the third region 31BR3 is greater than a ratio of the number of the first ligands in the fourth region 31BR4 to a total number of ligands in the fourth region 31BR4 obtained by combining the number of the first ligands in the fourth region 31BR4 and the number of the second ligands in the fourth region 31BR4.

A ratio of the number of fluorine atoms, which are the first ligands, to a total number of ligands per quantum dot (QD) contained in the second region 31RR2 of the red light-emitting layer 31R is preferably 0% or more and 82% or less, a ratio of the number of fluorine atoms, which are the first ligands, to a total number of ligands per quantum dot (QD) contained in the fourth region 31RR4 of the red light-emitting layer 31R is preferably more than 82% and 90% or less, and a ratio of the number of fluorine atoms, which are the first ligands, to a total number of ligands per quantum dot (QD) contained in the third region 31RR3 of the red light-emitting layer 31R is preferably more than 90% and 100% or less. A ratio of the number of fluorine atoms, which are the first ligands, to a total number of ligands per quantum dot (QD) contained in the second region 31GR2 of the green light-emitting layer 31G is preferably 0% or more and 82% or less, a ratio of the number of fluorine atoms, which are the first ligands, to a total number of ligands per quantum dot (QD) contained in the fourth region 31GR4 of the green light-emitting layer 31G is preferably more than 82% and 90% or less, and a ratio of the number of fluorine atoms, which are the first ligands, to a total number of ligands per quantum dot (QD) contained in the third region 31GR3 of the green light-emitting layer 31G is preferably more than 90% and 100% or less. A ratio of the number of fluorine atoms, which are the first ligands, to the total number of ligands per quantum dot (QD) contained in the second region 31BR2 of the blue light-emitting layer 31B is preferably 0% or more and 82% or less, a ratio of the number of fluorine atoms, which are the first ligands, to a total number of ligands per quantum dot (QD) contained in the fourth region 31BR4 of the blue light-emitting layer 31B is preferably more than 82% and 90% or less, and a ratio of the number of fluorine atoms, which are the first ligands, to a total number of ligands per quantum dot (QD) contained in the third region 31BR3 of the blue light-emitting layer 31B is preferably more than 90% and 100% or less. According to such a configuration, by reducing the ratio of the first ligands in the fourth region, which is less affected by impurities or the like, than the third region, which is more affected by impurities or the like, in each color light-emitting layer, protection of the quantum dots (QDs) in the third region of each color light-emitting layer can be efficiently stronger than protection of the quantum dots (QDs) in the fourth region while reducing an amount of the first ligands compared to the case in the first embodiment described above in which the ratio of the first ligands is equal throughout the first region.

Note that as described above in the first embodiment, the width of the first region, that is, the peripheral width, is preferably from 1 μm to 4 μm, so a combined width of a width of the third region and a width of the fourth region is also preferably from 2 μm to 4 μm. The width of the third region and the width of the fourth region may be substantially the same.

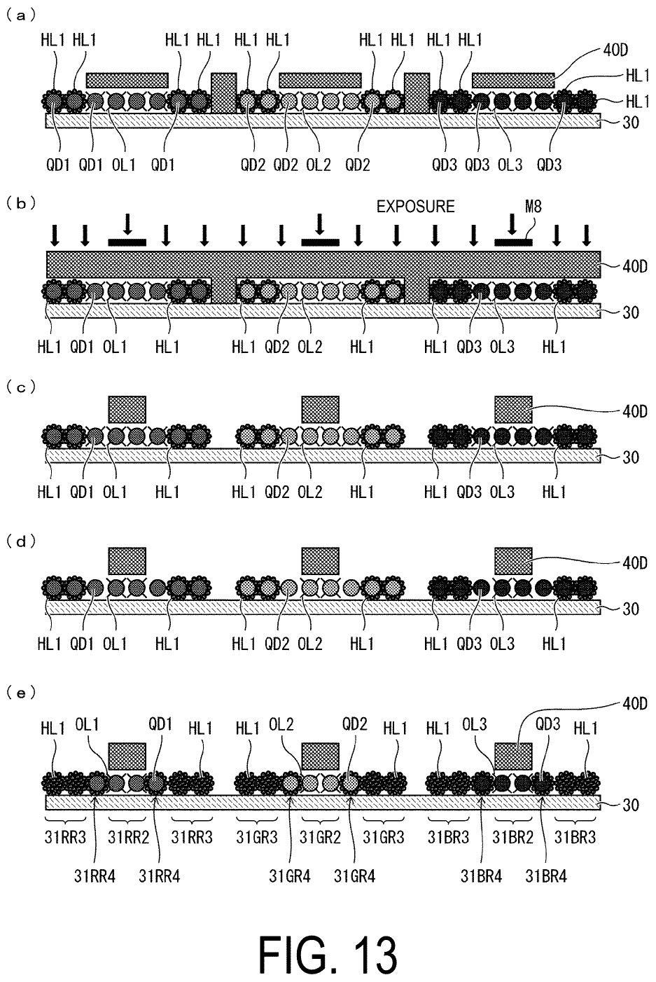

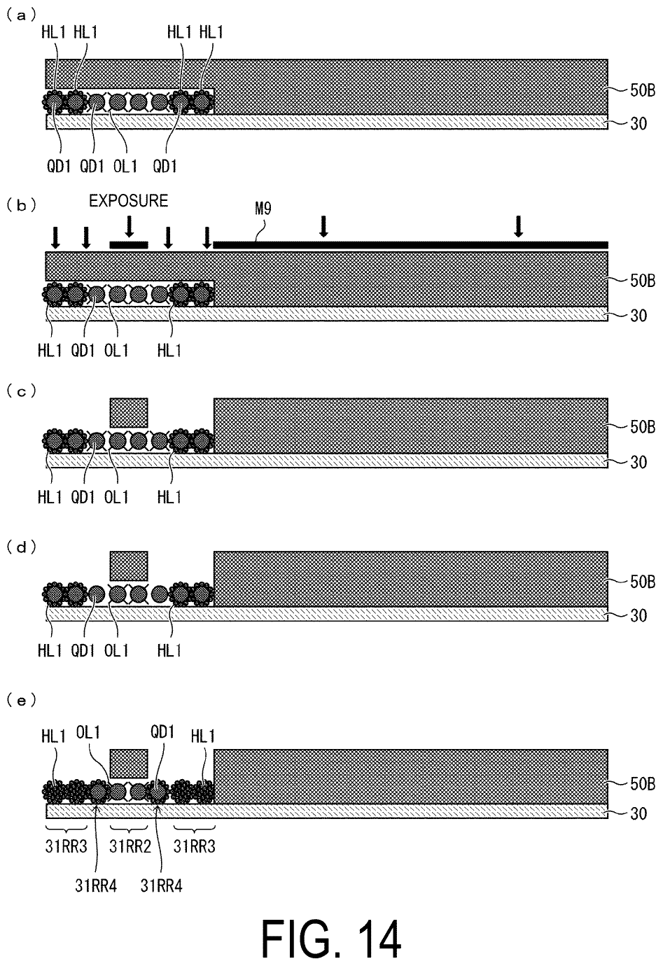

In the following, with reference to FIGS. 13 and 14, steps of the process of forming the light-emitting layers included in the light-emitting elements included in the respective subpixels of the display device 1a according to the second embodiment will be described.

(a) to (e) of FIG. 13 are diagrams illustrating some steps of the process of forming the light-emitting layers included in the light-emitting elements included in the respective subpixels of the display device 1a according to the second embodiment.

(a) of FIG. 13 is the same as (d) of FIG. 7 and illustrates a state in which a step of incorporating first ligands HL1 into a red light-emitting quantum dot layer 41R, a green light-emitting quantum dot layer 41G, and a blue light-emitting quantum dot layer 41B is performed.

Thereafter, as illustrated in (b) of FIG. 13, by forming a photosensitive resin material on at least the first region of the red light-emitting quantum dot layer 41R, the first region of the green light-emitting quantum dot layer 41G, and the first region of the blue light-emitting quantum dot layer 41B, a photosensitive resin layer 40D is formed again, and the photosensitive resin layer 40D is exposed using a mask M8. In the present embodiment, by forming the photosensitive resin material not only on the first region of the red light-emitting quantum dot layer 41R, the first region of the green light-emitting quantum dot layer 41G, and the first region of the blue light-emitting quantum dot layer 41B, but also above an entire hole transport layer 30, the photosensitive resin layer 40D is formed again, but the material application is not limited thereto.

Then, by developing, as illustrated in (c) of FIG. 13, the photosensitive resin layer 40D is removed on a partial region of the red light-emitting quantum dot layer 41R, which includes the first region of the red light-emitting quantum dot layer 41R and is wider than the first region of the red light-emitting quantum dot layer 41R, a partial region of the green light-emitting quantum dot layer 41G, which includes the first region of the green light-emitting quantum dot layer 41G and is wider than the first region of the green light-emitting quantum dot layer 41G, and a partial region of the blue light-emitting quantum dot layer 41B, which includes the first region of the blue light-emitting quantum dot layer 41B and is wider than the first region of the blue light-emitting quantum dot layer 41B. In the present embodiment, as illustrated in (c) of FIG. 13, the photosensitive resin layer 40D is removed in a frame shape, but the removing manner is not limited thereto.

Thereafter, as illustrated in (d) of FIG. 13, before a step of further incorporating the first ligands HL1 illustrated in (e) of FIG. 13, a washing step is performed to remove the organic ligands OL1, OL2, and OL3. Note that at this time, the first ligands HL1 already coordinated to the quantum dots (QDs) are not removed because these first ligands HL1 have a strong coordination force to the quantum dots (QDs). Thus, by performing the washing step of removing the organic ligands OL1, OL2, and OL3, a ratio of the organic ligands OL1, OL2, and OL3 to the first ligands HL1 in the fourth region can be easily adjusted.

Then, as illustrated in (e) of FIG. 13, the step of further incorporating the first ligands HL1 is performed. In the present embodiment, the step of further incorporating the first ligands HL1 is performed by forming a layer obtained by a solution containing the first ligands HL1, which are at least one type of ligand selected from a ligand being a halogen atom and a ligand being a sulfur atom, on a region including at least part of the end portion of the red light-emitting quantum dot layer 41R and different from the first region of the red light-emitting quantum dot layer 41R, a region including at least part of the end portion of the green light-emitting quantum dot layer 41G and different from the first region of the green light-emitting quantum dot layer 41G, and a region including at least part of the end portion of the blue light-emitting quantum dot layer 41B and different from the first region of the blue light-emitting quantum dot layer 41B. After the step of further incorporating the first ligands HL1, a step of removing solvents (e.g., a heat treatment step or a drying step) may be performed as necessary. A contained amount of the first ligands HL1 in the solution is within a range in which the first ligands HL1 can be dissolved or dispersed in the solvent to be used, and can be appropriately determined in consideration of an amount of the first ligands HL1 to be incorporated.

Thereafter, although not illustrated, a photosensitive resin layer removal step of removing the photosensitive resin layer 40D is performed to form the red light-emitting layer 31R including the second region 31RR2, the third region 31RR3, and the fourth region 31RR4, the green light-emitting layer 31G including the second region 31GR2, the third region 31GR3, and the fourth region 31GR4, and the blue light-emitting layer 31B including the second region 31BR2, the third region 31BR3, and the fourth region 31BR4 on the hole transport layer 30.

Note that in the present embodiment, in the step of further incorporating the first ligands HL1 described above, the first ligands HL1 are further incorporated into a region including the first region and wider than the first region as the region different from the first region of each color light-emitting quantum dot layer, so that the first region obtained combining the third region and the fourth region is expanded, but this step is not limited thereto. For example, in the step of further incorporating the first ligands HL1 described above, the first ligands HL1 may be further incorporated into a region including at least part of the end portion of each color light-emitting quantum dot layer and part of the first region, as the region different from the first region of each color light-emitting quantum dot layer.

According to the manufacturing method described above, since the steps illustrated in (a) to (e) of FIG. 13 are performed for all of the red light-emitting quantum dot layer 41R, the green light-emitting quantum dot layer 41G, and the blue light-emitting quantum dot layer 41B formed by the method illustrated in FIG. 6, the number of manufacturing steps can be reduced.

(a) to (e) of FIG. 14 are diagrams illustrating some steps of still another process of forming the light-emitting layers included in the light-emitting elements included in the respective subpixels of the display device 1a according to the second embodiment.

(a) of FIG. 14 is the same as (j) of FIG. 9 and illustrates a state in which a step of forming a second photosensitive resin layer 50B again by forming a photosensitive resin material on the first region of the red light-emitting quantum dot layer 41R after the step of incorporating the first ligands HL1 into the red light-emitting quantum dot layer 41R is performed.

Thereafter, as illustrated in (b) and (c) of FIG. 14, by exposing and developing the second photosensitive resin layer 50B using a mask M9, the second photosensitive resin layer 50B on a partial region of the red light-emitting quantum dot layer 41R, which includes the first region of the red light-emitting quantum dot layer 41R and is wider than the first region of the red light-emitting quantum dot layer 41R, is removed. In the present embodiment, as illustrated in (c) of FIG. 14, the second photosensitive resin layer 50B is removed in a frame shape, but the removing manner is not limited thereto.

Thereafter, as illustrated in (d) of FIG. 14, before a step of further incorporating the first ligands HL1 illustrated in (e) of FIG. 14, a washing step is performed to remove the organic ligand OL1. Note that at this time, the first ligands HL1 already coordinated to the quantum dots (QDs) are not removed because these first ligands HL1 have a strong coordination force to the quantum dots (QDs). Thus, by performing the washing step of removing the organic ligand OL1, a ratio of the organic ligand OL1 to the first ligands HL1 in the fourth region can be easily adjusted.

Then, as illustrated in (e) of FIG. 14, the step of further incorporating the first ligands HL1 is performed. In the present embodiment, the step of further incorporating the first ligands HL1 is performed by forming a layer obtained by a solution containing the first ligands HL1, which are at least one type of ligand selected from a ligand being a halogen atom and a ligand being a sulfur atom, on a region including at least part of the end portion of the red light-emitting quantum dot layer 41R and different from the first region of the red light-emitting quantum dot layer 41R. After the step of further incorporating the first ligands HL1, a step of removing solvents (e.g., a heat treatment step or a drying step) may be performed as necessary. A contained amount of the first ligands HL1 in the solution is within a range in which the first ligands HL1 can be dissolved or dispersed in the solvent to be used, and can be appropriately determined in consideration of an amount of the first ligands HL1 to be incorporated.

Thereafter, although not illustrated, a step of forming the second photosensitive resin layer 50B is performed again, and the steps illustrated in FIGS. 10 and 11 can be performed.

Although the step of further incorporating the first ligands HL1 is described with reference to FIG. 14, the step of further incorporating the first ligands is not limited thereto, and after the step illustrated in (i) of FIG. 10, as in FIG. 14, a step of further incorporating the first ligands HL2 into the green light-emitting quantum dot layer 41G can be performed, and after the step illustrated in (i) of FIG. 11, as in FIG. 14, a step of further incorporating the first ligands HL3 into the blue light-emitting quantum dot layer 41B can be performed. Note that in the present embodiment, different types of ligands are used for the first ligands HL1, the first ligands HL2, and the first ligands HL3, so the most preferable type of ligand can be selected for the quantum dots contained in each color light-emitting layer.

### Third Embodiment

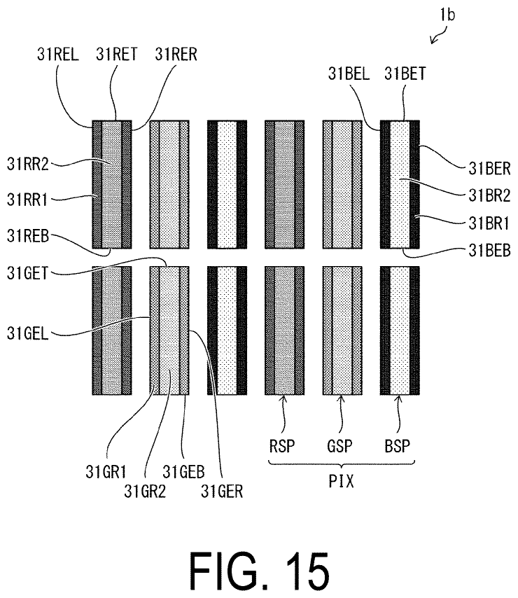

Next, with reference to FIG. 15, a third embodiment of the disclosure will be described. A display device 1b according to the present embodiment is different from the display devices described in the first and the second embodiments in that in each of a red light-emitting layer 31R, a green light-emitting layer 31G, and a blue light-emitting layer 31B, a first region includes a first island-shaped portion including one of two facing end portions of each color light-emitting layer and a second island-shaped portion including another of the two facing end portions of each color light-emitting layer, and a second region is sandwiched between the first island-shaped portion and the second island-shaped portion. The others are as described in the first and second embodiments. For convenience of description, members having the same functions as the members illustrated in the diagrams in the first and second embodiments are denoted by the same reference signs, and descriptions thereof will be omitted.

FIG. 15 is a plan view of light-emitting layers included in light-emitting elements included in subpixels of the display device 1b according to the third embodiment, respectively.

As illustrated in FIG. 15, a first region 31RR1 of the red light-emitting layer 31R included in a red light-emitting element 5R included in a red subpixel RSP includes a first island-shaped portion including one of two facing end portions 31REL and 31RER of the red light-emitting layer 31R and a second island-shaped portion including another of the two facing end portions 31REL and 31RER of the red light-emitting layer 31R, and a second region 31RR2 of the red light-emitting layer 31R is sandwiched between the first island-shaped portion and the second island-shaped portion. A first region 31GR1 of the green light-emitting layer 31G included in a green light-emitting element 5G included in a green subpixel GSP includes a first island-shaped portion including one of two facing end portions 31GEL and 31GER of the green light-emitting layer 31G and a second island-shaped portion including another of the two facing end portions 31GEL and 31GER of the green light-emitting layer 31G, and a second region 31GR2 of the green light-emitting layer 31G is sandwiched between the first island-shaped portion and the second island-shaped portion. A first region 31BR1 of the blue light-emitting layer 31B included in a blue light-emitting element 5B included in a blue subpixel BSP includes a first island-shaped portion including one of two facing end portions 31BEL and 31BER of the blue light-emitting layer 31B and a second island-shaped portion including another of the two facing end portions 31BEL and 31BER of the blue light-emitting layer 31B, and a second region 31BR2 of the blue light-emitting layer 31B is sandwiched between the first island-shaped portion and the second island-shaped portion. Note that in the present embodiment, a case in which the two facing end portions of each color light-emitting layer are the right end portion and the left end portion in the figure is described as an example, but the position of the two facing end portions is not limited thereto, and the two facing end portions of each color light-emitting layer may be an upper end portion and a lower end portion in the figure.

With such a configuration, it is possible to obtain light-emitting elements and a display device capable of protecting the quantum dots in the peripheral portions of the light-emitting layers, that is, capable of securing reliability, while further improving the light-emitting characteristics of the light-emitting layers, compared to the first and second embodiments described above.

Each color light-emitting layer included in the display device 1b illustrated in FIG. 15 can be formed by performing the steps illustrated in (c), (d), and (e) of FIG. 7 in a state in which in the step of patterning the photosensitive resin layer 40D illustrated in (a) and (b) of FIG. 7, the photosensitive resin layer 40D on the first region including the first island-shaped portion including one of the two facing end portions and the second island-shaped portion including the other of the two facing end portions of each of the red light-emitting quantum dot layer 41R, the green light-emitting quantum dot layer 41G, and the blue light-emitting quantum dot layer 41B is removed, while the photosensitive resin layer 40D on the second region other than the first region is left.

### Fourth Embodiment

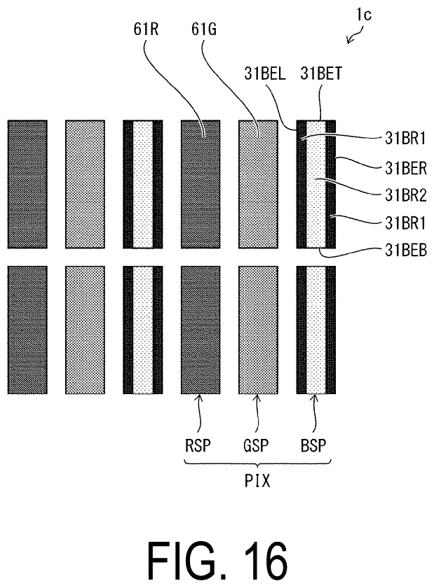

Next, a fourth embodiment of the disclosure will be described based on FIG. 16. A display device 1c according to the present embodiment is different from the display device described in the third embodiment in that only a first region of a blue light-emitting layer 31B includes a first island-shaped portion including one of two facing end portions of the blue light-emitting layer 31B and a second island-shaped portion including another of the two facing end portions of the blue light-emitting layer 31B, and a second region of the blue light-emitting layer 31B is sandwiched between the first island-shaped portion and the second island-shaped portion. The other details are as described in the third embodiment. For convenience of explanation, members having the same functions as those of the members illustrated in the drawings in the third embodiment are denoted by the same reference signs, and descriptions thereof will be omitted.

FIG. 16 is a plan view of light-emitting layers included in light-emitting elements included in subpixels of the display device 1c according to the fourth embodiment, respectively.

As illustrated in FIG. 16, a first region 31BR1 of the blue light-emitting layer 31B included in a blue light-emitting element 5B included in a blue subpixel BSP includes a first island-shaped portion including one of two facing end portions 31BEL and 31BER of the blue light-emitting layer 31B and a second island-shaped portion including another of the two facing end portions 31BEL and 31BER of the blue light-emitting layer 31B, and a second region 31BR2 of the blue light-emitting layer 31B is sandwiched between the first island-shaped portion and the second island-shaped portion. Note that in the present embodiment, a case in which the two facing end portions of the blue light-emitting layer 31B are the right end portion and the left end portion in the figure is described as an example, but the position of the two facing end portions is not limited thereto, and the two facing end portions of the blue light-emitting layer 31B may be an upper end portion and a lower end portion in the figure.

Note that as illustrated in FIG. 16, a red light-emitting layer 61R included in a red light-emitting element 5R included in a red subpixel RSP and a green light-emitting layer 61G included in a green light-emitting element 5G included in a green subpixel GSP are known light-emitting layers that do not include the first region and the second region described above.

With such a configuration, it is possible to obtain a display device in which reliability for the blue light-emitting layer, which is less reliable than the red light-emitting layer and the green light-emitting layer, can be ensured, and light-emitting characteristics for the red light-emitting layer and the green light-emitting layer can be sufficiently ensured.

In the present embodiment, a case in which only the blue light-emitting layer 31B includes the first region 31BR1 and the second region 31BR2 is described as an example. However, this case is just an example, and only the red light-emitting layer 31R may include a first region 31RR1 and a second region 31RR2, or only the green light-emitting layer 31G may include a first region 31GR1 and a second region 31GR2.

### APPENDIX

The disclosure is not limited to each of the embodiments described above, and various modifications may be made within the scope of the claims. Embodiments obtained by appropriately combining technical approaches disclosed in each of the different embodiments also fall within the technical scope of the disclosure. Furthermore, novel technical features can be formed by combining the technical approaches disclosed in each of the embodiments.

### INDUSTRIAL APPLICABILITY

The disclosure can be applied to a light-emitting element, a display device, a method of manufacturing a light-emitting element, and a method of manufacturing a display device.

1. A light-emitting element comprising:
a first electrode and a second electrode; and
a function layer placed between the first electrode and the second electrode and including at least a light-emitting layer containing quantum dots,
wherein the light-emitting layer contains at least some amounts of first ligands, the first ligands being at least one type of ligand selected from a ligand being a halogen atom and a ligand being a sulfur atom, and includes a first region being a partial region of the light-emitting layer including at least part of an end portion of the light-emitting layer and a second region other than the first region, and
the number of the first ligands contained per unit volume in the first region is greater than the number of the first ligands contained per unit volume in the second region.

2. A light-emitting element comprising:
a first electrode and a second electrode; and
a function layer placed between the first electrode and the second electrode and including at least a light-emitting layer containing quantum dots,
wherein the light-emitting layer contains at least some amounts of first ligands and second ligands, the first ligands being at least one type of ligand selected from a ligand being a halogen atom and a ligand being a sulfur atom, the second ligands being ligands other than the first ligands, and includes a first region being a partial region of the light-emitting layer including at least part of an end portion of the light-emitting layer and a second region other than the first region, and
a ratio of the number of the first ligands in the first region to a total number of ligands in the first region obtained by combining the number of the first ligands in the first region and the number of the second ligands in the first region is greater than a ratio of the number of the first ligands in the second region to a total number of ligands in the second region obtained by combining the number of the first ligands in the second region and the number of the second ligands in the second region.

3. The light-emitting element according to claim 1,
wherein the first ligands are contained in the first region and the second region of the light-emitting layer.

4. The light-emitting element according to claim 1,
wherein the first ligands are contained only in the first region of the light-emitting layer.

5. The light-emitting element according to claim 1,
wherein the light-emitting layer contains second ligands other than the first ligands.

6. The light-emitting element according to claim 1,
wherein the light-emitting layer contains second ligands other than the first ligands, types of the second ligands include an organic ligand, and
organic ligands are contained in the first region and the second region of the light-emitting layer, each of the organic ligands is identical to the organic ligand.

7-8. (canceled)

9. The light-emitting element according to claim 1,
wherein the first region includes a first island-shaped portion including one of two facing end portions of the light-emitting layer and a second island-shaped portion including another of the two facing end portions of the light-emitting layer, and
the second region is sandwiched between the first island-shaped portion and the second island-shaped portion.

10. The light-emitting element according to claim 1,
wherein the first region is a partial region of the light-emitting layer including an entire end portion of the light-emitting layer, and
the second region is surrounded by the first region.

11. The light-emitting element according to claim 1,
wherein the first region includes multiple sub-regions,
two sub-regions adjacent to each other being the multiple sub-regions are an inner sub-region provided closer to the second region and an outer sub-region provided farther from the second region, and
the number of the first ligands contained per unit volume in the outer sub-region is greater than the number of the first ligands contained per unit volume in the inner sub-region.

12. The light-emitting element according to claim 1,
wherein the light-emitting layer contains second ligands other than the first ligands,
the first region includes multiple sub-regions,
two sub-regions adjacent to each other being the multiple sub-regions are an inner sub-region provided closer to the second region and an outer sub-region provided farther from the second region, and
a ratio of the number of the first ligands in the outer sub-region to a total number of ligands in the outer sub-region obtained by combining the number of the first ligands in the outer sub-region and the number of the second ligands in the outer sub-region is greater than a ratio of the number of the first ligands in the inner sub-region to a total number of ligands in the inner sub-region obtained by combining the number of the first ligands in the inner sub-region and the number of the second ligands in the inner sub-region.

13. The light-emitting element according to claim 1,
wherein the first ligands are ligands being halogen atoms.

14. The light-emitting element according to claim 1,
wherein a ratio of an area of the first region to an area of the light-emitting layer is from 8.5% to 33%.

15. The light-emitting element according to claim 1,
wherein a width of the first region being the shortest distance from an edge of the light-emitting layer to the second region is 1 μm or more.

16. The light-emitting element according to claim 1,
wherein a width of the first region being the shortest distance from an edge of the light-emitting layer to the second region is 4 μm or less.

17. The light-emitting element according to claim 1,
wherein the first ligands are fluorine atoms.

18. A display device comprising:
the light-emitting element according to claim 1.

19-20. (canceled)

21. A method of manufacturing a light-emitting element comprising:
forming a first electrode;
forming a first light-emitting layer on the first electrode; and
forming a second electrode on the first light-emitting layer,
wherein the forming a first light-emitting layer includes
forming a first quantum dot layer on the first electrode,
forming a photosensitive resin layer on an entire surface,
by exposing and developing the photosensitive resin layer, removing the photosensitive resin layer on a first region being a partial region of the first quantum dot layer including at least part of an end portion of the first quantum dot layer and leaving the photosensitive resin layer on a second region of the first quantum dot layer other than the first region,
forming a layer obtained by a solution containing first ligands on the first region of the first quantum dot layer, the first ligands being at least one type of ligand selected from a ligand being a halogen atom and a ligand being a sulfur atom, and
after the forming a layer obtained by a solution containing first ligands on the first region of the first quantum dot layer, removing the photosensitive resin layer.

22. The method of manufacturing a light-emitting element according to claim 21,
wherein in the forming a first electrode, multiple first electrodes are formed, each of the multiple first electrodes identical to the first electrode, and
in the forming a first quantum dot layer, the first quantum dot layer is formed on some first electrodes among the multiple first electrodes.

23-27. (canceled)

28. The method of manufacturing a light-emitting element according to claim 21,
wherein in the forming a first quantum dot layer, the first quantum dot layer is formed using a first quantum dot solution containing first quantum dots and the first ligands.

29. The method of manufacturing a light-emitting element according to claim 21,
wherein in the forming a first quantum dot layer, the first quantum dot layer is formed using a first quantum dot solution containing first quantum dots and organic ligands.

30-36. (canceled)
